(19) United States
(12) Patent Application Publication
(10) Pub. No.: US 2025/0063792 A1
(43) Pub. Date: Feb. 20, 2025

(54) CONTACT GATE ISOLATION

(71) Applicant: Taiwan Semiconductor Manufacturing Company, Ltd., Hsin-Chu (TW)

(72) Inventors: Jia-Chuan YOU, Taoyuan County (TW); Chia-Hao CHANG, Hsinchu City (TW); Chu-Yuan HSU, Taichung City (TW); Kuo-Cheng CHIANG, Hsinchu County (TW); Chih-Hao WANG, Hsinchu (TW)

(21) Appl. No.: 18/526,473

(22) Filed: Dec. 1, 2023

Related U.S. Application Data
(60) Provisional application No. 63/519,899, filed on Aug. 16, 2023.

(51) Int. Cl. H01L 29/66; H01L 21/8234; H01L 27/088; H01L 29/06; H01L 29/08; H01L 29/423; H01L 29/775; H01L 29/786

(52) U.S. Cl. CPC H01L 29/66545; H01L 21/823412; H01L 21/823418; H01L 21/823468; H01L 21/823475; H01L 21/823481; H01L 27/088; H01L 29/0673; H01L 29/0847; H01L 29/42392; H01L 29/66439; H01L 29/6656; H01L 29/775; H01L 29/78696

(57) ABSTRACT

Gate isolation processes (e.g., gate-to-source/drain contact isolation) are described herein. An exemplary contact gate isolation process may include recessing (e.g., by etching) sidewall portions of a high-k gate dielectric and gate spacers of a gate structure to form a contact gate isolation (CGI) opening that exposes sidewalls of a gate electrode of the gate structure, forming a gate isolation liner along the sidewalls of the gate electrode that partially fills the CGI opening, and forming a gate isolation layer over the gate isolation liner that fills a remainder of the CGI opening. A dielectric constant of the gate isolation liner is less than a dielectric constant of the high-k gate dielectric. A dielectric constant of the gate isolation layer is less than a dielectric constant of the high-k gate dielectric. A dielectric constant of the gate isolation layer may be less than a dielectric constant of the gate isolation layer.

### PRIORITY CLAIM

This is a non-provisional application of and claims benefit of U.S. Provisional Application No. 63/519,899, filed Aug. 16, 2023, the entire disclosure of which is incorporated herein by reference.

### BACKGROUND

The electronics industry is experiencing an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure, which can extend around the channel region and provide access to the channel on two or four sides. GAA devices are compatible with conventional complementary metal-oxide-semiconductor (CMOS) processes, and their structure allows them to be aggressively scaled-down while maintaining gate control and mitigating SCEs. GAA devices provide a channel in a silicon nanowire/nanosheet. However, integration of fabrication of the GAA features around the nanowire/nanosheet can be challenging. For example, while current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1A is a perspective view illustrating of the formation of a semiconductor structure at one of the intermediate stages, in accordance with some embodiments of the disclosure.

FIG. 1B is a perspective view illustrating of the formation of a semiconductor structure at one of the intermediate stages, in accordance with some embodiments of the disclosure.

FIG. 1C is a perspective view illustrating of the formation of a semiconductor structure at one of the intermediate stages, in accordance with some embodiments of the disclosure.

FIGS. 1D-1 and 1D-2 are cross-sectional views illustrating of the formation of a semiconductor structure at one of the intermediate stages, in accordance with some embodiments of the disclosure.

FIGS. 1E-1 and 1E-2 are cross-sectional views illustrating of the formation of a semiconductor structure at one of the intermediate stages, in accordance with some embodiments of the disclosure.

FIG. 1F is a perspective view illustrating of the formation of a semiconductor structure at one of the intermediate stages, in accordance with some embodiments of the disclosure.

FIGS. 1F-1 and 1F-2 are cross-sectional views of the semiconductor structure of FIG. 1F, in accordance with some embodiments of the disclosure.

FIG. 1G is a perspective view illustrating of the formation of a semiconductor structure at one of the intermediate stages, in accordance with some embodiments of the disclosure.

FIGS. 1G-1 and 1G-2 are cross-sectional views of the semiconductor structure of FIG. 1F, in accordance with some embodiments of the disclosure.

FIG. 1G-3 is an enlarged view of FIG. 1G-2 to illustrate more details, in accordance with some embodiments of the disclosure.

FIGS. 1H-1 and 1H-2 are cross-sectional views illustrating of the formation of a semiconductor structure at one of the intermediate stages, in accordance with some embodiments of the disclosure.

FIG. 11 is a perspective view illustrating of the formation of a semiconductor structure at one of the intermediate stages, in accordance with some embodiments of the disclosure.

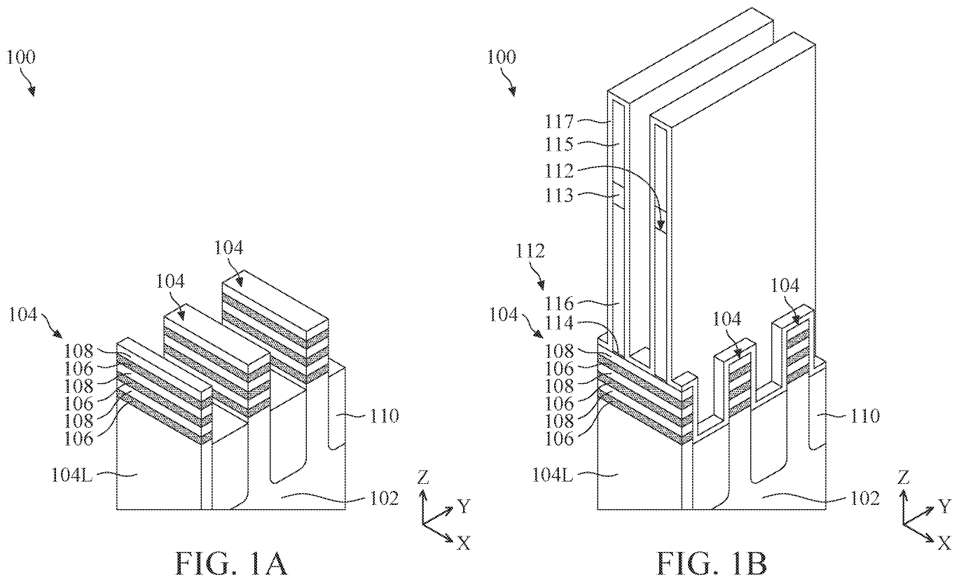

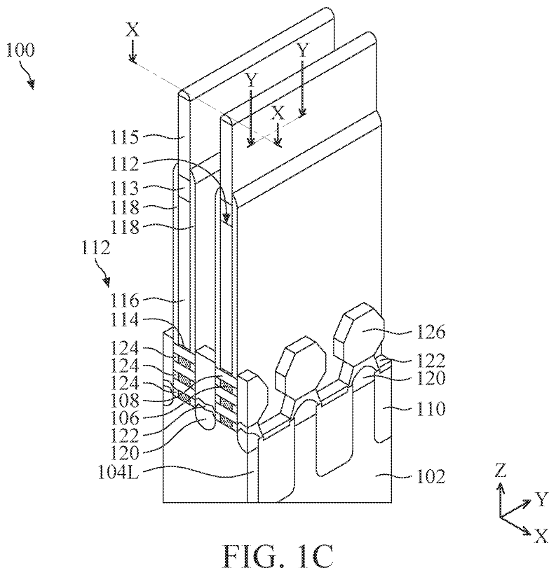

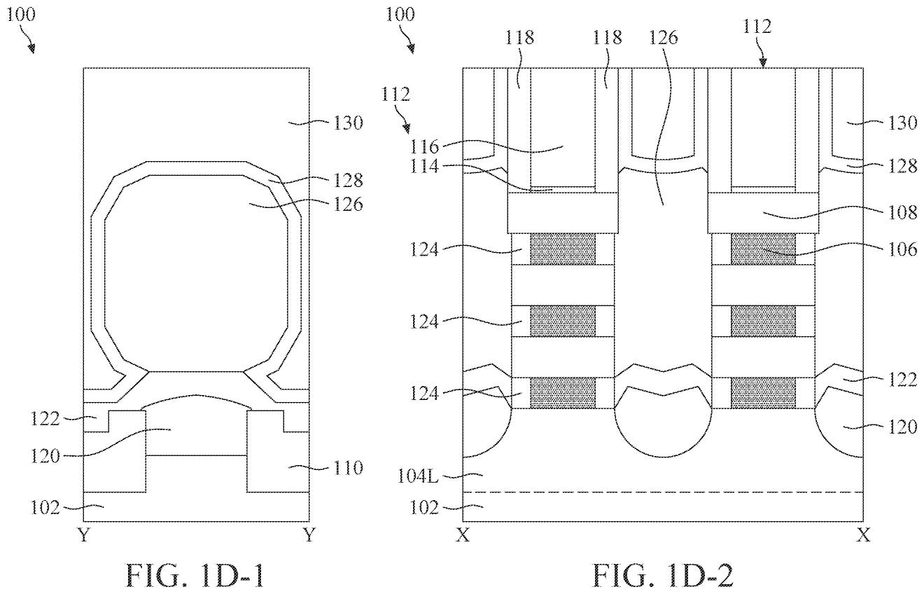

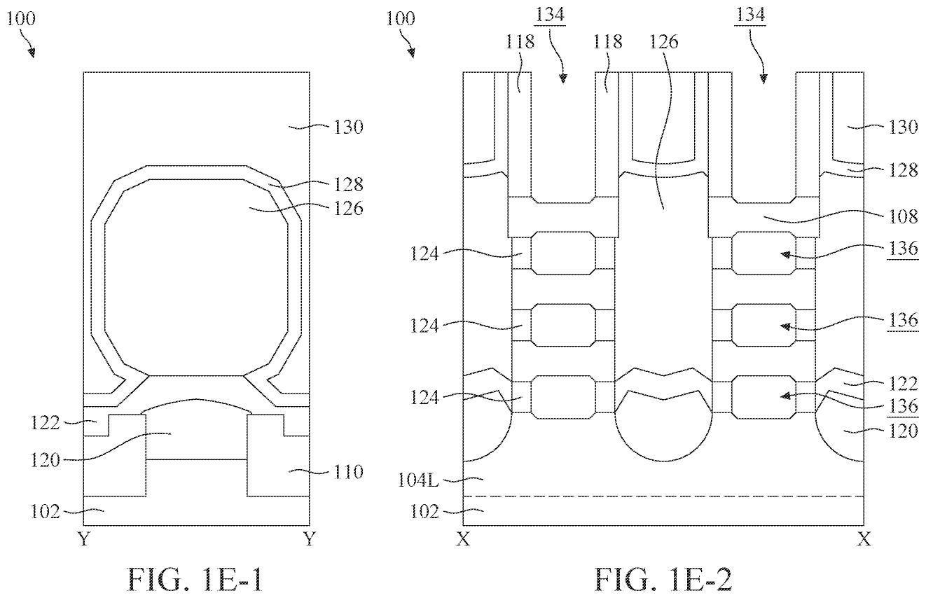

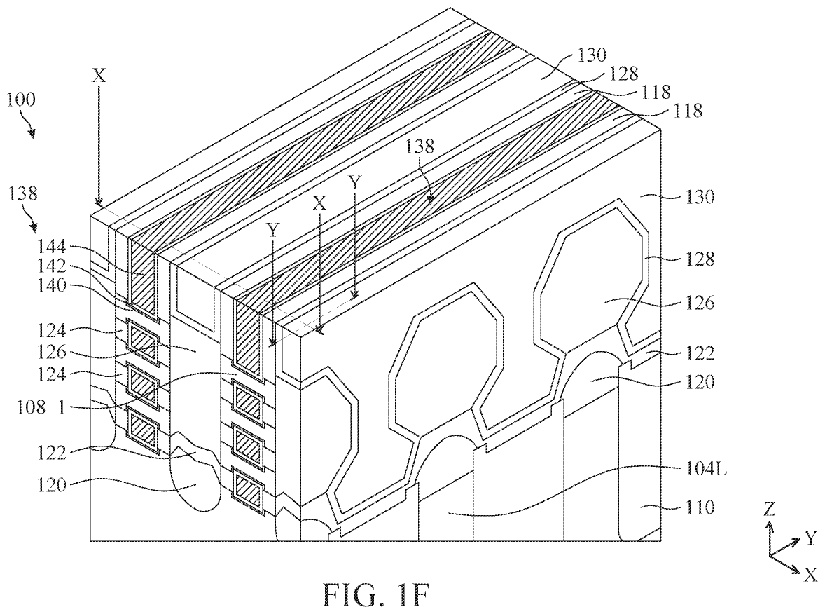

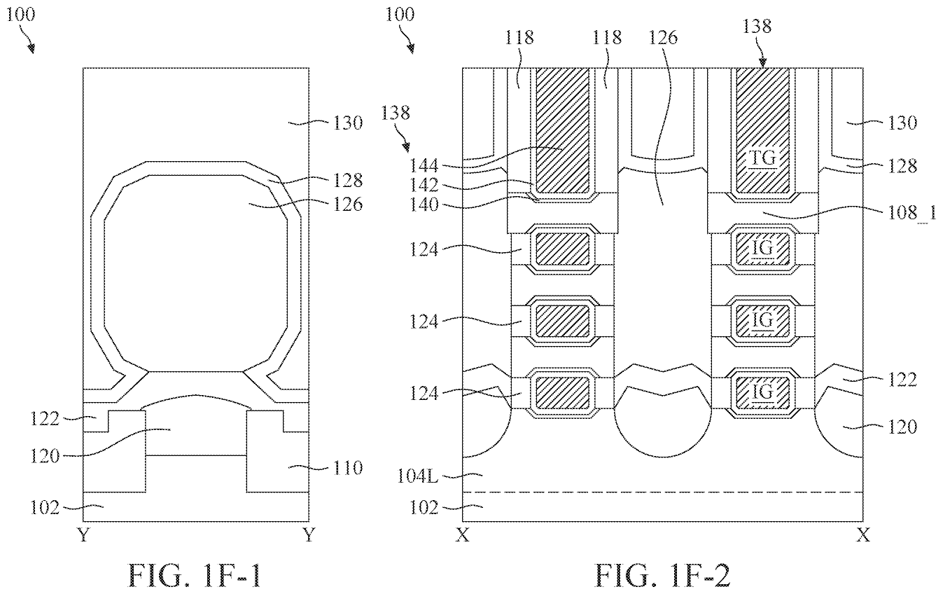

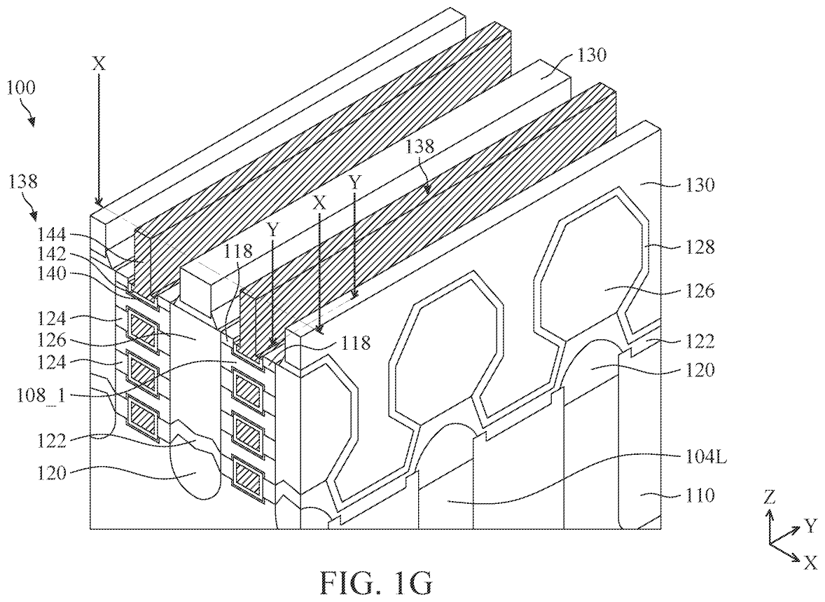

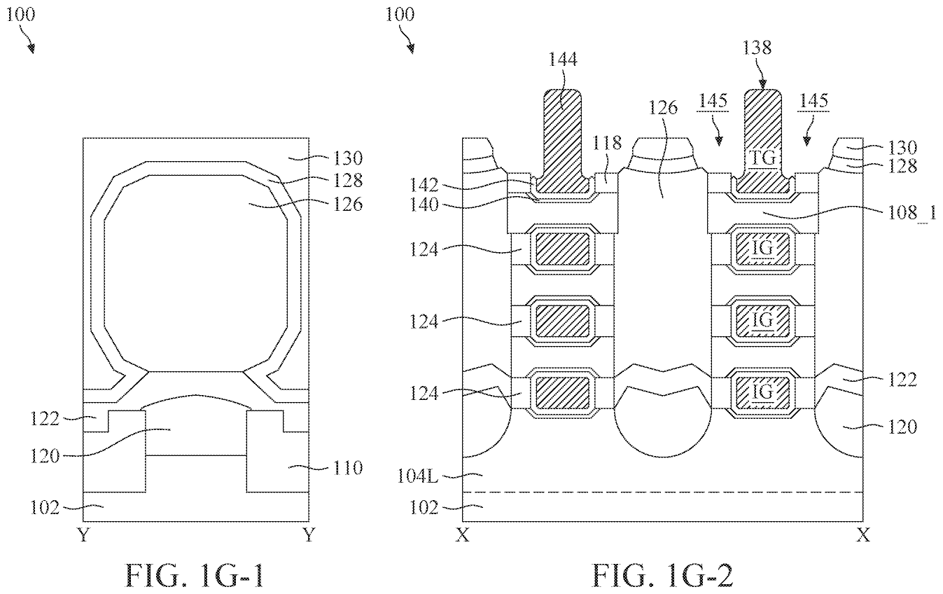

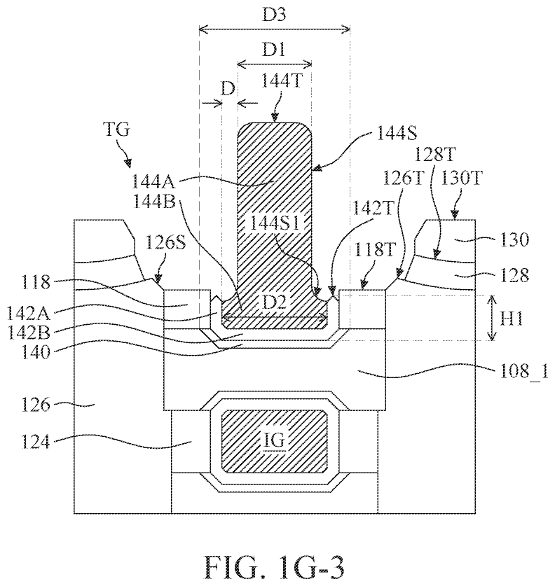

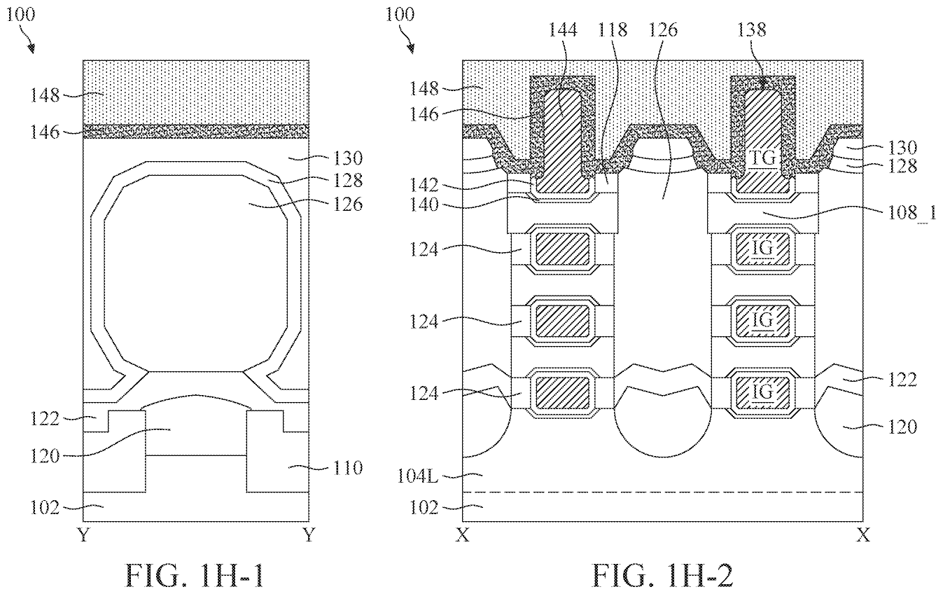

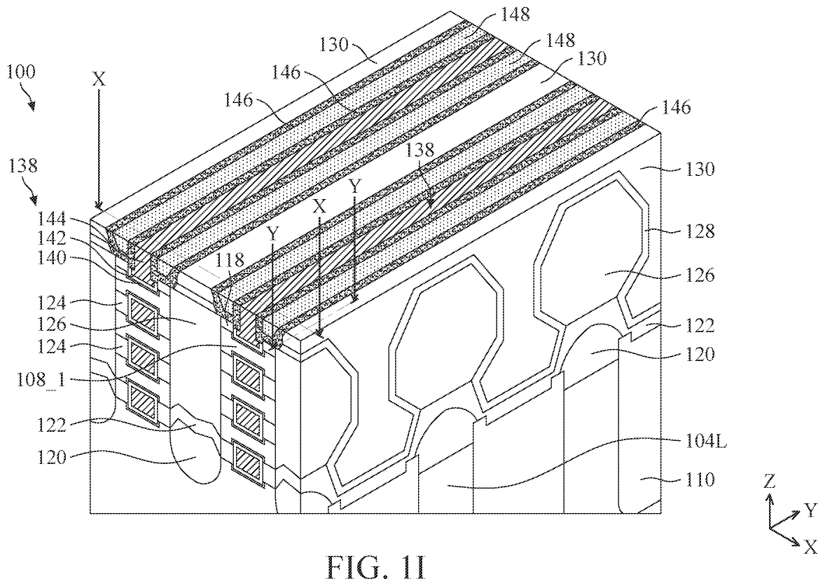

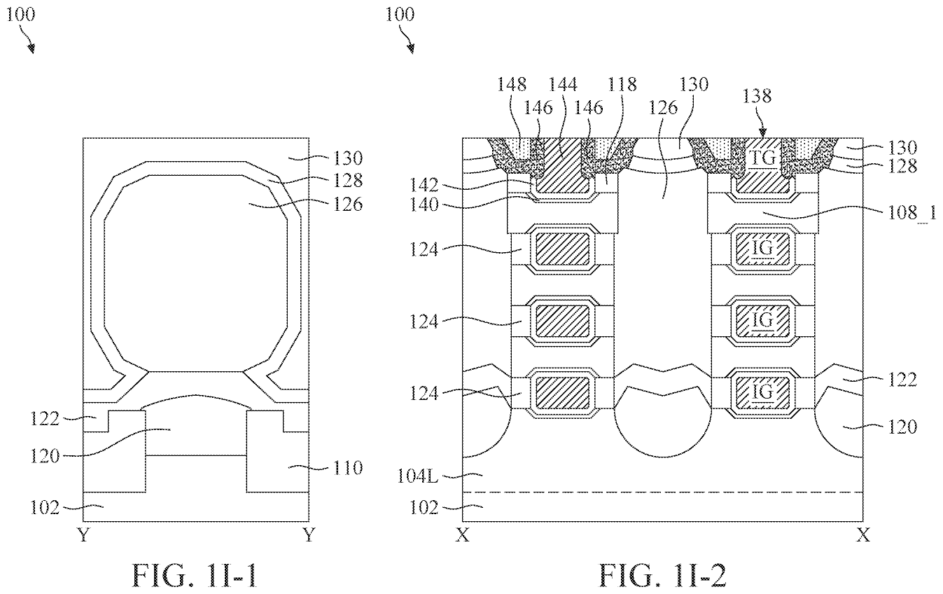

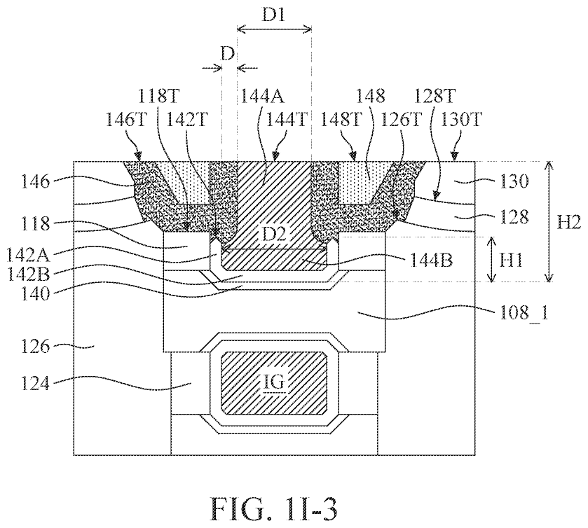

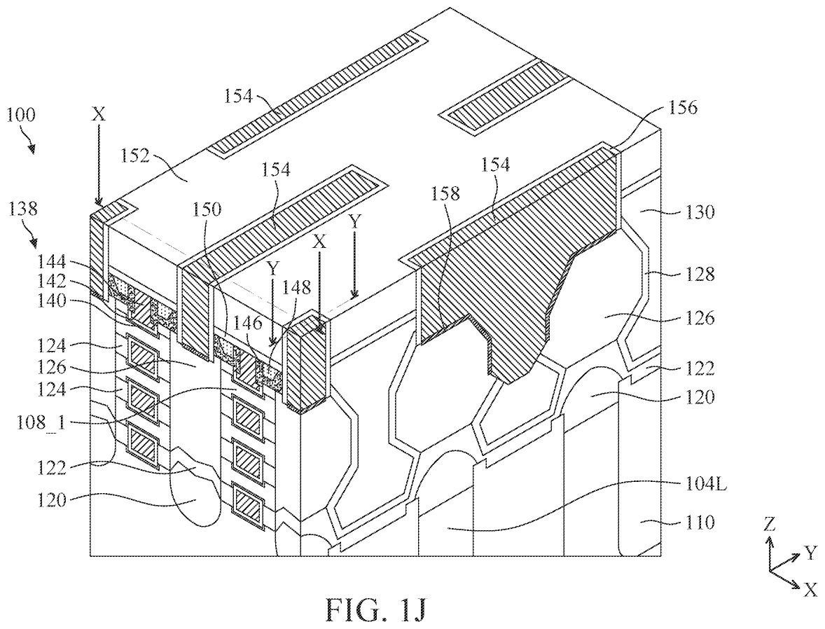

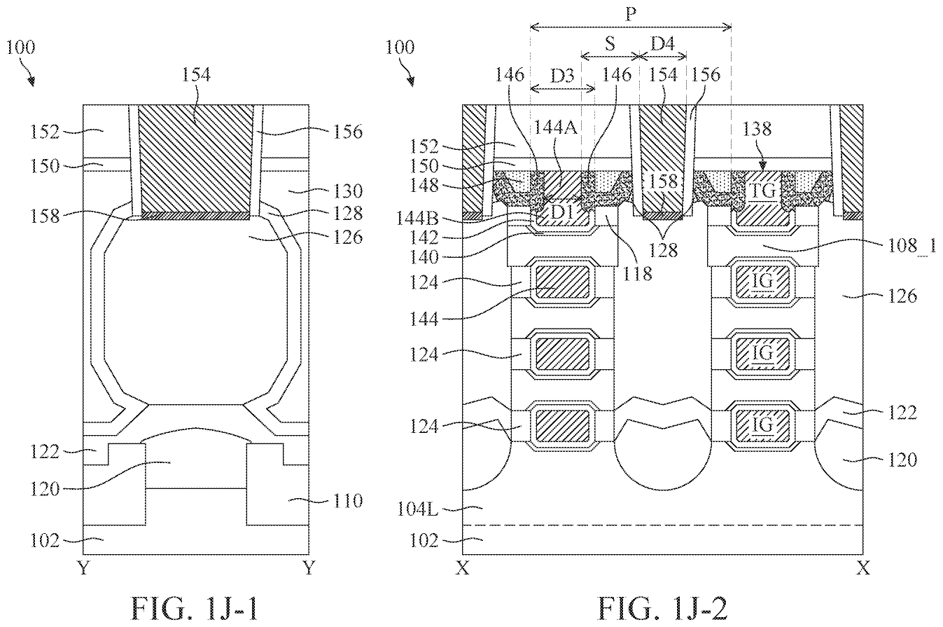

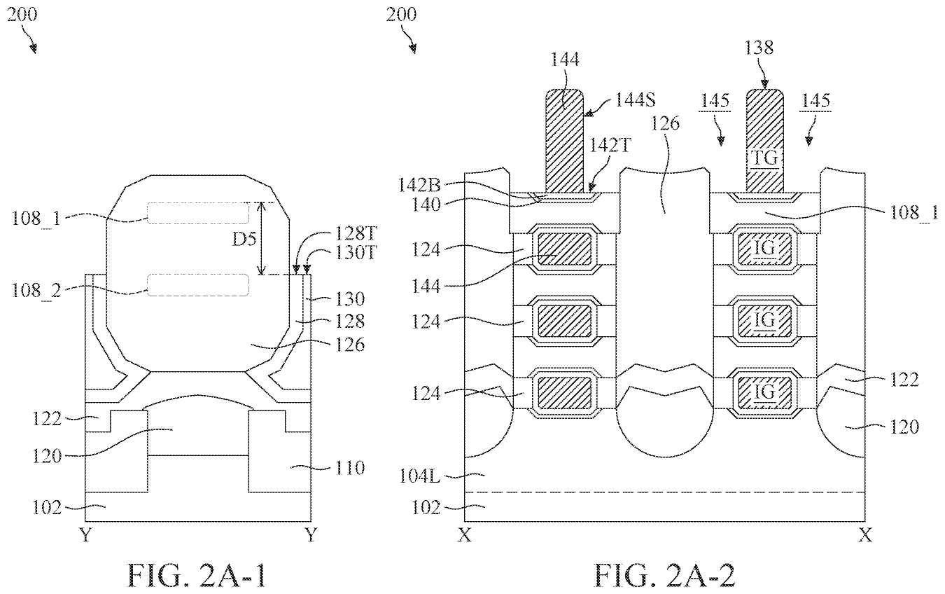

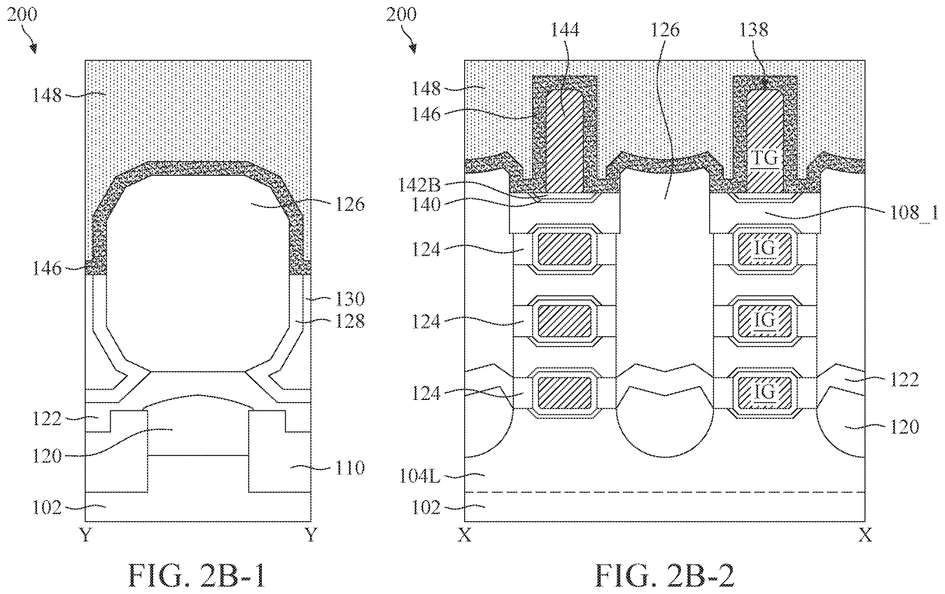

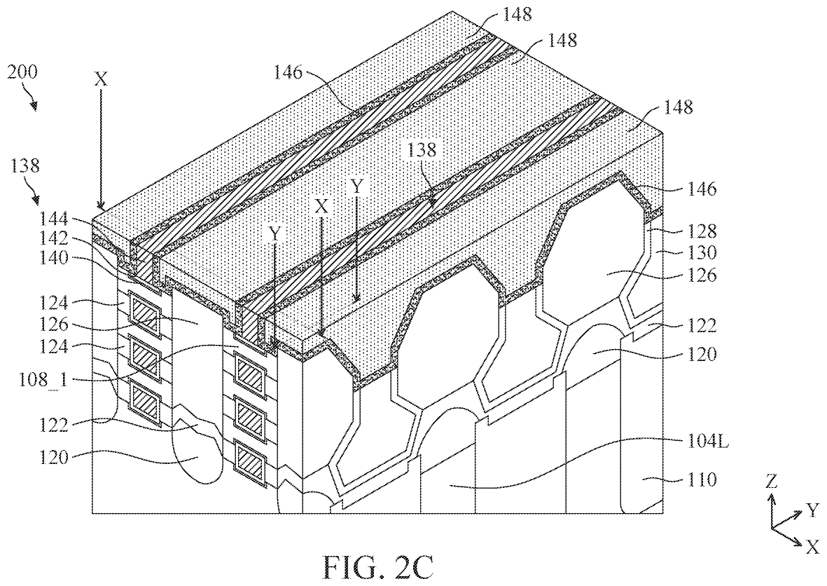

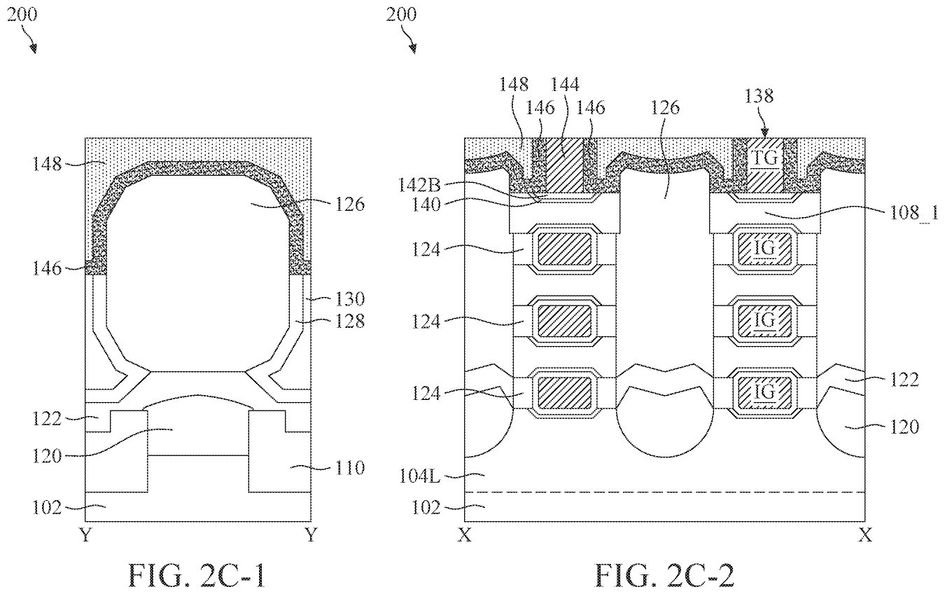

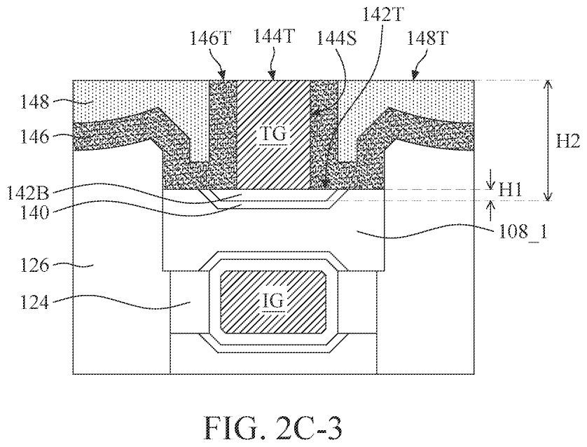

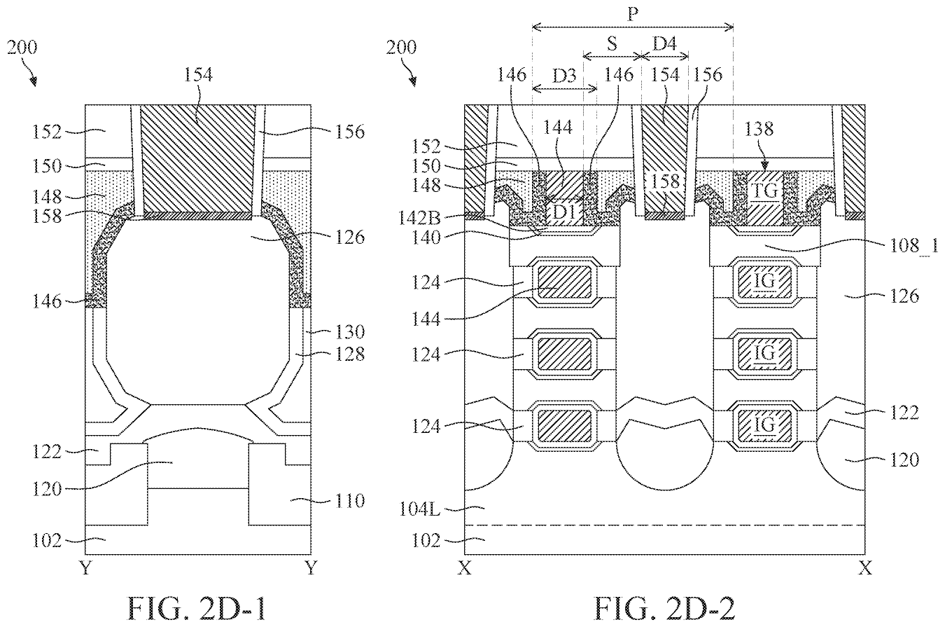

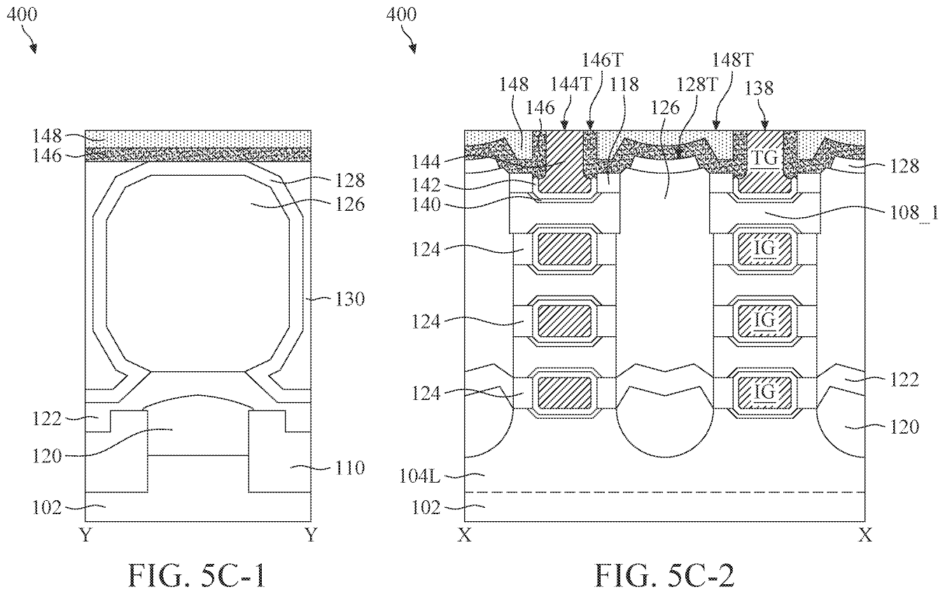

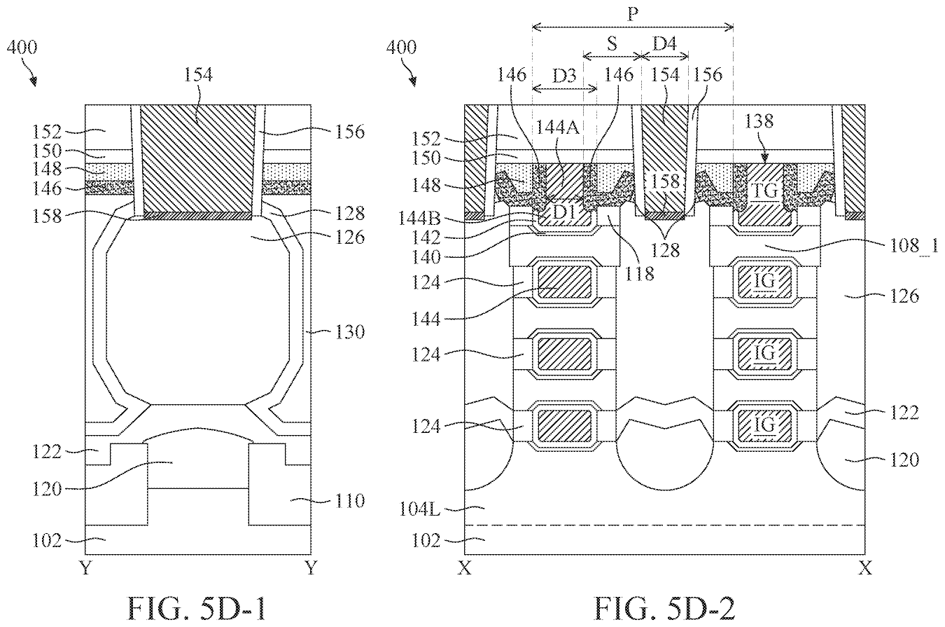

FIGS. 1I-1 and 1I-2 are cross-sectional views of the semiconductor structure of FIG. 11, in accordance with some embodiments of the disclosure.

FIG. 1I-3 is an enlarged view of FIG. 1J-2 to illustrate more details, in accordance with some embodiments of the disclosure.

FIG. 1J is a perspective view illustrating of the formation of a semiconductor structure at one of the intermediate stages, in accordance with some embodiments of the disclosure.

FIGS. 1J-1 and 1J-2 are cross-sectional views of the semiconductor structure of FIG. 1J, in accordance with some embodiments of the disclosure.

FIGS. 2A-1 and 2A-2 are cross-sectional views illustrating of the formation of a semiconductor structure at one of the intermediate stages, in accordance with some embodiments of the disclosure.

FIGS. 2B-1 and 2B-2 are cross-sectional views illustrating of the formation of a semiconductor structure at one of the intermediate stages, in accordance with some embodiments of the disclosure.

FIG. 2C is a perspective view illustrating of the formation of a semiconductor structure at one of the intermediate stages, in accordance with some embodiments of the disclosure.

FIGS. 2C-1 and 2C-2 are cross-sectional views of the semiconductor structure of FIG. 2C, in accordance with some embodiments of the disclosure.

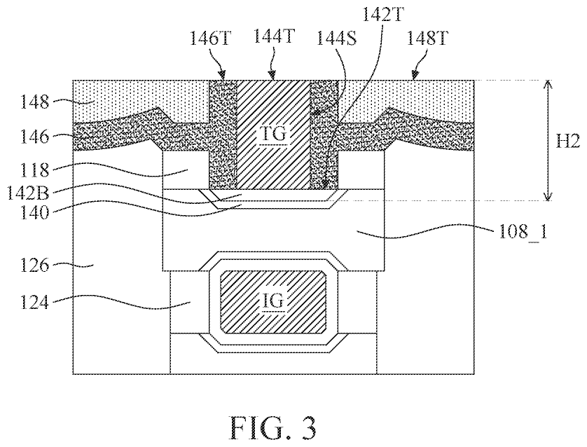

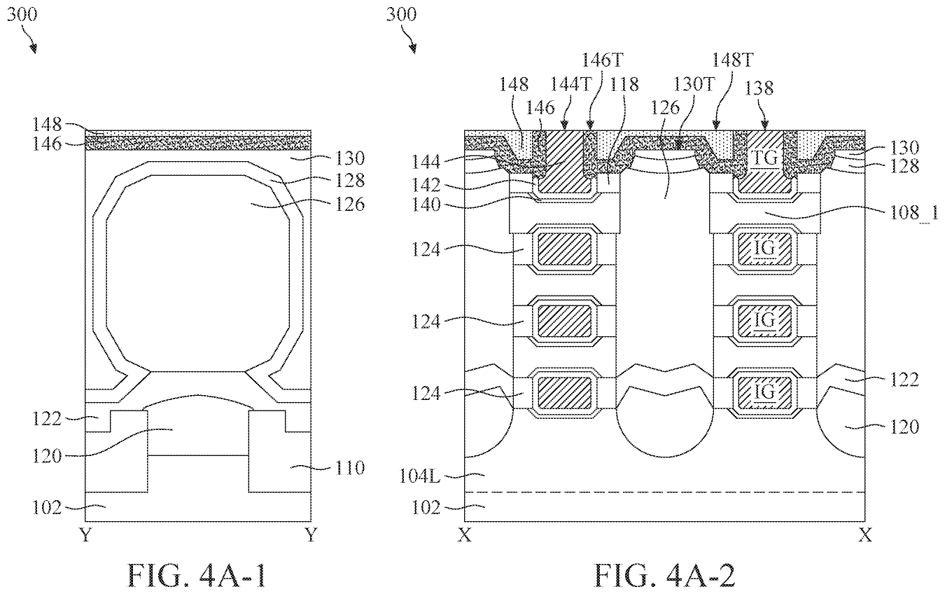

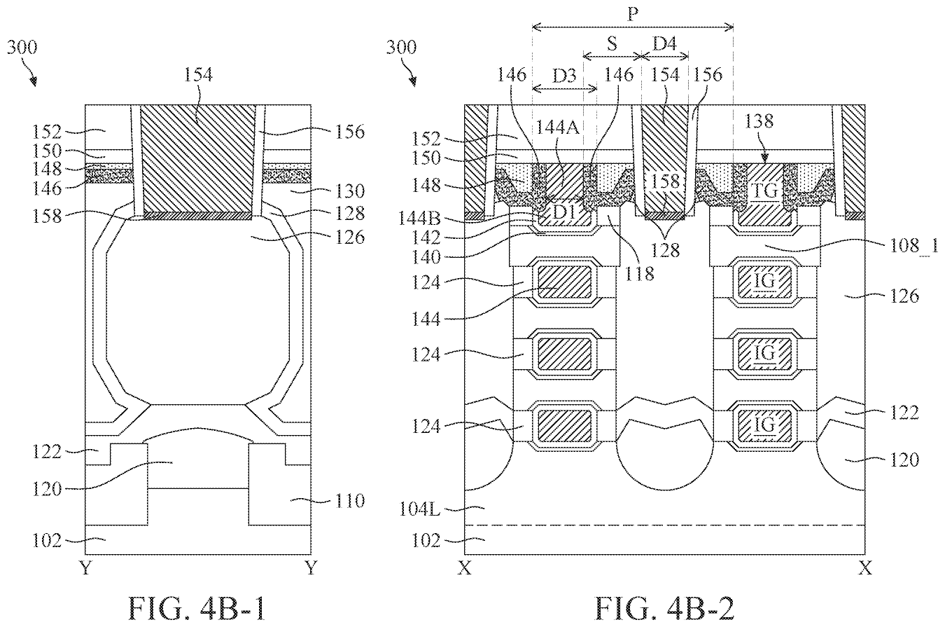

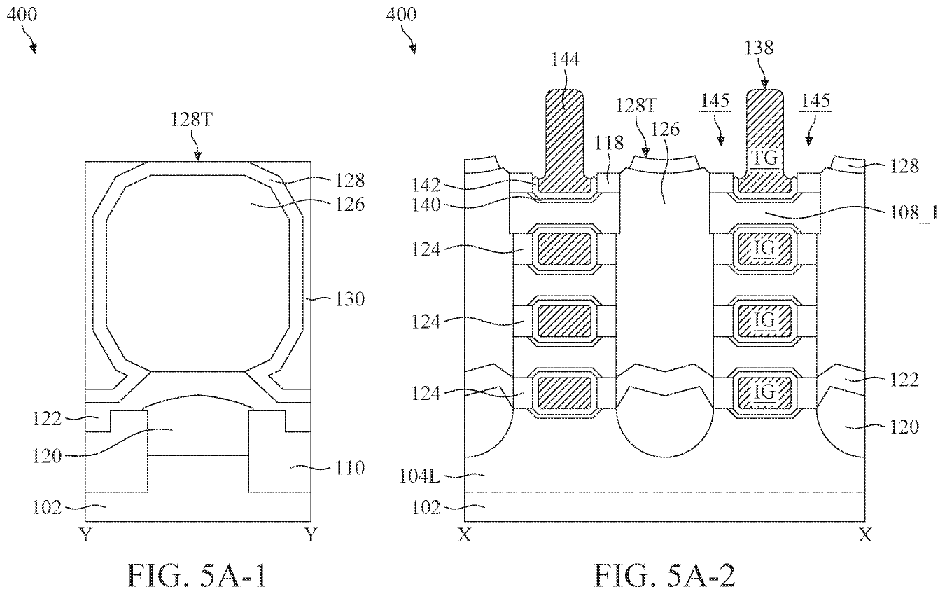

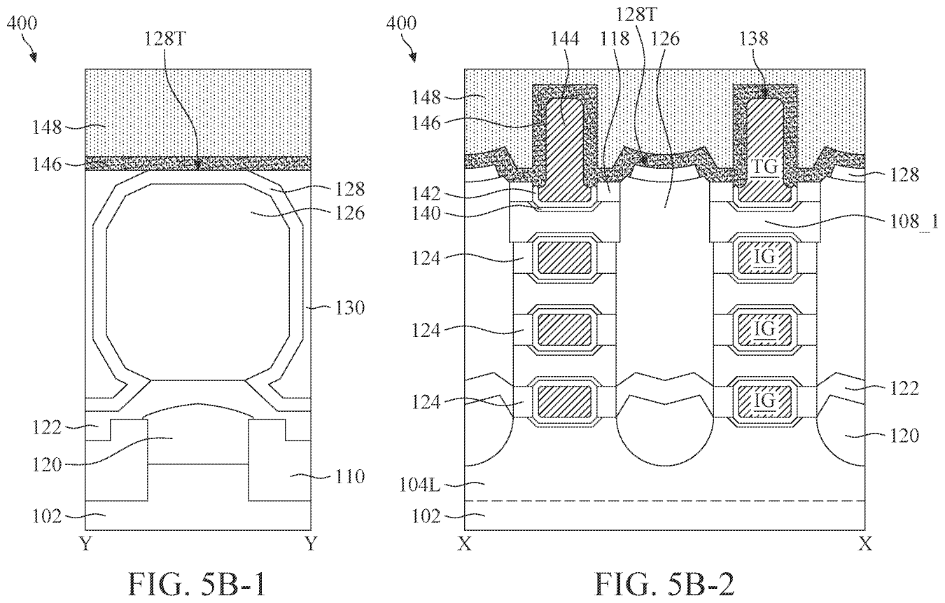

FIG. 2C-3 is an enlarged view of FIG. 2C-2 to illustrate more details, in accordance with some embodiments of the disclosure.

FIGS. 2D-1 and 2D-2 are cross-sectional views illustrating of the formation of a semiconductor structure at one of the intermediate stages, in accordance with some embodiments of the disclosure.

FIG. 3 illustrates a modification the semiconductor structure of FIG. 2C-3, in accordance with some embodiments of the disclosure.

FIGS. 4A-1 and 4A-2 are cross-sectional views illustrating of the formation of a semiconductor structure at one of the intermediate stages, in accordance with some embodiments of the disclosure.

FIGS. 4B-1 and 4B-2 are cross-sectional views illustrating of the formation of a semiconductor structure at one of the intermediate stages, in accordance with some embodiments of the disclosure.

FIGS. 5A-1 and 5A-2 are cross-sectional views illustrating of the formation of a semiconductor structure at one of the intermediate stages, in accordance with some embodiments of the disclosure.

FIGS. 5B-1 and 5B-2 are cross-sectional views illustrating of the formation of a semiconductor structure at one of the intermediate stages, in accordance with some embodiments of the disclosure.

FIGS. 5C-1 and 5C-2 are cross-sectional views illustrating of the formation of a semiconductor structure at one of the intermediate stages, in accordance with some embodiments of the disclosure.

FIGS. 5D-1 and 5D-2 are cross-sectional views illustrating of the formation of a semiconductor structure at one of the intermediate stages, in accordance with some embodiments of the disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Furthermore, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The nanostructure transistor (e.g., nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of a semiconductor structure and a method for forming the semiconductor structure are provided. The method includes recessing the gate dielectric layer to expose the top gate electrode layer. As a result, the dimension of the top portion of the final gate stack may be reduced, and the spacing between the contact plug and the final gate stack may thus increase. Therefore, the reliability of the resulting semiconductor device may improve. In addition, the overlay window of the photolithography process for forming the contact opening may be relaxed, which may facilitate the scaling down of the gate-to-gate pitch.

FIGS. 1A through 1J-2 are schematic views illustrating the formation of a semiconductor structure 100 at various intermediate stages, in accordance with some embodiments of the disclosure. FIG. 1A is a perspective view of the semiconductor structure 100 after the formation of active regions 104 and an isolation structure 110, in accordance with some embodiments of the disclosure.

A semiconductor structure 100 is provided, as shown in FIG. 1, in accordance with some embodiments. The semiconductor structure 100 includes a substrate 102 and active regions 104 and an isolation structure 110 over the substrate 102, in accordance with some embodiments.

For a better understanding of the semiconductor structure, X-Y-Z coordinate reference is provided in the figures of the present disclosure. The X-axis and the Y-axis are generally orientated along the lateral (or horizontal) directions that are parallel to the main surface of the substrate 102. The Y-axis is transverse (e.g., substantially perpendicular) to the X-axis. The Z-axis is generally oriented along the vertical direction that is perpendicular to the main surface of the substrate 102 (or the X-Y plane).

The substrate 102 may be a portion of a semiconductor wafer, a semiconductor chip (or die), and the like. In some embodiments, the substrate 102 is a silicon substrate. In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GaInP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

The active regions 104 extend in the X direction, in accordance with some embodiments. The active regions 104 have longitudinal axes parallel to the X direction, in accordance with some embodiments. In some embodiments, the active regions 104 are also referred to as fins or fin structures. Each of the active regions 104 is defined as several channel regions and several source/drain regions, where the channel regions and the source/drain regions are alternately arranged, in accordance with some embodiments. In this disclosure, a source/drain refers to a source and/or a drain. It is noted that in the present disclosure, a source and a drain are interchangeably used and the structures thereof are substantially the same. The X direction may also be referred to as the channel-extending direction. The current of the resulting semiconductor device (i.e., nanostructure transistor) flows in the X direction through the channel. Gate structures or gate stacks will be formed with longitudinal axes parallel to the Y direction and extend over the channel regions of the active regions 104. The Y direction may also be referred to as a gate-extending direction.

Each of the active regions 104 includes a lower fin element 104L surrounded by the isolation structure 110 and an upper fin element formed from an epitaxial stack including alternating first semiconductor layers 106 and second semiconductor layer 108, in accordance with some embodiments. The formation of the active regions 104 includes forming an epitaxial stack over the substrate 102 using an epitaxial growth process, in accordance with some embodiments. The epitaxial stack may be formed by depositing a first semiconductor layer 106 on the substrate 102, depositing a second semiconductor layer 108 on the first semiconductor layer 106, and repeating the cycle of depositing the semiconductor layers 106 and 108 several times. The first semiconductor layers 106 and the second semiconductor layers 108 are alternately stacked, in accordance with some embodiments. The epitaxial growth process may be molecular beam epitaxy (MBE), metal organic chemical vapor deposition (MOCVD), or vapor phase epitaxy (VPE), or another suitable technique.

In some embodiments, the first semiconductor layers 106 are made of a first semiconductor material and the second semiconductor layers 108 are made of a second semiconductor material with a different composition than the first semiconductor material. The first semiconductor material for the first semiconductor layers 106 has a different lattice constant than the second semiconductor material for the second semiconductor layers 108, in accordance with some embodiments. In some embodiments, the first semiconductor material and the second semiconductor material have different oxidation rates and/or etching selectivity. In some embodiments, the first semiconductor layers 106 are made of SiGe, where the percentage of germanium (Ge) in the SiGe is in a range from about 20 atomic % to about 50 atomic %, and the second semiconductor layers 108 are made of pure or substantially pure silicon. In some embodiments, the first semiconductor layers 106 are Si₁₋ₓGeₓ, where x is more than about 0.3, or Ge (x=1.0) and the second semiconductor layers 108 are Si or Si_{1-y}Ge_{y}, where y is less than about 0.4, and x>y.

The first semiconductor layers 106 are configured as sacrificial layers and will be removed to form gaps to accommodate gate materials, in accordance with some embodiments. The second semiconductor layers 108 will form nanostructures (e.g., nanowires or nanosheets) that laterally extend between source/drain features and serve as the channel for the resulting semiconductor device (such as a nanostructure transistor), in accordance with some embodiments. As the term is used herein, “nanostructures” refers to semiconductor layers that have cylindrical shape, bar shaped and/or sheet shape. A gate stack (not shown) will be formed across and wrap around the nanostructures, in accordance with some embodiments. Although three first semiconductor layers 106 and three second semiconductor layers 108 are shown in FIG. 1A, the number is not limited to three, and can be two or four, and is less than ten.

In some embodiments, the thickness of each of the first semiconductor layers 106 is in a range from about 3 nm to about 20 nm, such as about 4 nm to about 12 nm. In some embodiments, the thickness of each of the second semiconductor layers 108 is in a range from about 3 nm to about 20 nm, such as about 4 nm to about 12 nm. The thickness of the second semiconductor layers 108 may be greater than, equal to, or less than the first semiconductor layers 106, which may depend on the amount of the gate materials to be filled in spaces where the first semiconductor layers 106 are removed.

The formation of the active regions 104 further includes patterning the epitaxial stack and the underlying substrate 102 using photolithography and etching processes, thereby forming trenches and the active regions 104 protruding from between trenches, in accordance with some embodiments. The portion of the substrate 102 protruding from between the trenches serves as the lower fin elements 104L of the active regions 104, in accordance with some embodiments. The remainder of the epitaxial stack (including the first semiconductor layers 106 and the second semiconductor layers 108) serves as the upper fin elements of the active regions 104, in accordance with some embodiments.

An isolation structure 110 is formed to surround the lower fin elements 104L of the active regions 104, as shown in FIG. 1A, in accordance with some embodiments. The isolation structure 110 is configured to electrically isolate active regions 104 of the semiconductor structure 100 and is also referred to as a shallow trench isolation (STI) feature, in accordance with some embodiments.

The formation of the isolation structure 110 includes forming an insulating material to overfill the trenches, in accordance with some embodiments. In some embodiments, the insulating material is made of silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof. In some embodiments, the insulating material is deposited using CVD (such as flowable CVD (FCVD), low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

A planarization process is performed on the insulating material to remove a portion of the insulating material above the active regions 104, in accordance with some embodiments. The planarization may be chemical mechanical polishing (CMP), etching back process, or a combination thereof. The insulating material is then recessed by an etching process (such as dry plasma etching and/or wet chemical etching) until the sidewalls of the upper fin elements of the active regions 104 are exposed, in accordance with some embodiments. The remaining insulating material serves as the isolation structure 110, in accordance with some embodiments.

FIG. 1B is a perspective view of the semiconductor structure 100 after the formation of dummy gate structures 112 and a spacer layer 117, in accordance with some embodiments of the disclosure.

Dummy gate structures 112 are formed across the active regions 104 and the isolation structure 110, as shown in FIG. 1B, in accordance with some embodiments. The dummy gate structures 112 are configured as sacrificial structures and will be replaced with the final gate stacks, in accordance with some embodiments. In some embodiments, the dummy gate structures 112 extend in the Y direction. The dummy gate structures 112 have longitudinal axes parallel to the Y direction, in accordance with some embodiments. The dummy gate structures 112 surround the channel regions of the active regions 104, in accordance with some embodiments.

Each of the dummy gate structures 112 includes a dummy gate dielectric layer 114 and a dummy gate electrode layer 116 formed over the dummy gate dielectric layer 114, as shown in FIG. 1B, in accordance with some embodiments. In some embodiments, the dummy gate dielectric layer 114 is conformally formed along the upper fin elements of the active regions 104. In some embodiments, the dummy gate dielectric layer 114 is made of one or more dielectric materials, such as silicon oxide (SiO), silicon nitride (SiN), silicon oxynitride (SiON), HfO₂, HfZrO, HfSiO, HfTiO, and/or HfAlO. In some embodiments, the dielectric material is deposited using ALD, CVD, thermal oxidation, physical vapor deposition (PVD), another suitable technique, or a combination thereof.

In some embodiments, the dummy gate electrode layer 116 is made of semiconductor materials such as polysilicon or poly-silicon germanium. In some embodiments, the material for the dummy gate electrode layer 116 is deposited using CVD, ALD, another suitable technique, or a combination thereof. In some embodiments, the formation of the dummy gate structures 112 includes globally and conformally depositing a dielectric material for the dummy gate dielectric layer 114 over the semiconductor structure 100, depositing a material for the dummy gate electrode layer 116 over the dielectric material, planarizing the material for the dummy gate electrode layer 116, and patterning the material for the dummy gate electrode layer 116 and the dielectric material into the dummy gate structures 112.

The patterning process includes forming a patterned mask including hard mask layers 113 and 115 over the material for the dummy gate electrode layer 116, in accordance with some embodiments. The hard mask layer 113 may be a silicon nitride layer, and the hard mask layer 115 may be a silicon oxide layer, in accordance with some embodiments. The patterned mask corresponds to and overlaps the channel regions of the active regions 104, in accordance with some embodiments. The materials for the dummy gate dielectric layer 114 and the dummy gate electrode layer 116, uncovered by the patterned mask, are etched away until the active regions 104 and the top surface of the isolation structure 110 are exposed, in accordance with some embodiments.

A spacer layer 117 is formed over the semiconductor structure 100, as shown in FIG. 1B, in accordance with some embodiments. In some embodiments, the spacer layer 117 is made of a dielectric material, such as silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof, or a combination thereof. In some embodiments, the spacer layer 117 is made of a low-k dielectric material with the dielectric constant (k) lower than 10. For example, the dielectric constant value of the gate spacer layers 118 may be lower than a k-value of silicon oxide (SiO), such as lower than 4.2, equal to or lower than about 3.9, such as in a range from about 3.5 to about 3.9. The spacer layer 117 is deposited using ALD, CVD (such as PECVD, LPCVD or HARP), another suitable technique, or a combination thereof.

FIG. 1C is a perspective view of the semiconductor structure 100 after the formation of gate spacer layers 118, semiconductor isolation structures 120, dielectric isolation structure 122, inner spacer layers 124 and source/drain features 126, in accordance with some embodiments of the disclosure.

An etching process is performed on the spacer layer 117, in accordance with some embodiments. The vertical portion of the spacer layer 117 on the opposite sides of the dummy gate structures 112 remain to form gate spacer layers 118, as shown in FIG. 1C, in accordance with some embodiments. The gate spacer layers 118 are used to offset the subsequently formed source/drain features and separate the source/drain features from the gate structure, in accordance with some embodiments. The gate spacer layers 118 may be also referred to as top spacer layers.

Source/drain features 126 are formed in and/or over the source/drain regions of the active regions 104, as shown in FIG. 1C, in accordance with some embodiments. The formation of the source/drain features 122 includes recessing the source/drain regions of the active regions 104 using the dummy gate structures 112 and the gate spacer layers 118 as masks to form source/drain recesses (where the source/drain features 122 are to be formed) on opposite sides of the dummy gate structures 112, in accordance with some embodiments. The source/drain recesses may extend into the lower fin elements 104L, in accordance with some embodiments. In some embodiments, the recessing process includes an anisotropic etching process such as dry plasma etching, an isotropic etching process such as dry chemical etching, remote plasma etching or wet chemical etching, or a combination thereof.

Afterward, an etching process is performed to laterally recess, from the source/drain recesses, the first semiconductor layers 106 of the active regions 104 thereby forming notches, and then inner spacer layers 124 are formed in the notches, as shown in FIG. 1C, in accordance with some embodiments. The inner spacer layers 124 are formed to abut the recessed side surfaces of the first semiconductor layers 106, in accordance with some embodiments. In some embodiments, the inner spacer layers 124 are located between adjacent second semiconductor layers 108 and between the lowermost second semiconductor layers 108 and the lower fin elements 104L. In some embodiments, the inner spacer layers 124 extend directly below the gate spacer layers 118.

In some embodiments, the inner spacer layers 124 are made of dielectric material silicon oxide (SiO₂), silicon nitride (SIN), silicon carbide (SiC), silicon oxynitride (SiON), silicon carbon nitride (SiCN), silicon oxycarbonitride (SiOCN), and/or oxygen-doped silicon carbonitride (Si(O)CN). In some embodiments, the inner spacer layers 124 are made of low-k dielectric materials with the dielectric constant lower than 10. For example, the dielectric constant value of the inner spacer layers 124 may be lower than a k-value of silicon oxide (SiO), such as lower than 4.2, equal to or lower than about 3.9, such as in a range from about 3.5 to about 3.9.

In some embodiments, the formation of the inner spacer layers 124 includes depositing a dielectric material for the inner spacer layers 124 over the semiconductor structure 100 to overfill the notches, and then etching away the portion of the dielectric material outside the notches. The portions of the inner spacer layers 124 remaining in the notches serve the inner spacer layers 124, in accordance with some embodiments.

Semiconductor isolation features 120 are formed in the source/drain recesses on the lower fin elements 104L using an epitaxial growth process, as shown in FIG. 1C, in accordance with some embodiments. The epitaxial growth process may be MBE, MOCVD, or VPE, another suitable technique, or a combination thereof. In some embodiments, the semiconductor isolation features 120 are made of undoped epitaxial material such as intrinsic silicon, intrinsic silicon germanium and/or another suitable semiconductor material. For example, an impurity (or an n-type dopant and/or a p-type dopant) in the semiconductor isolation feature 120 has a concentration of less than about 10¹⁴ cm⁻³. In some other embodiments, the semiconductor isolation features 120 are doped with dopant having the opposite conductivity type to the source/drain features 126.

Afterward, the dielectric isolation features 122 are formed in the source/drain recesses on the semiconductor isolation features 120, and on the isolation structure 110, as shown in FIG. 1C, in accordance with some embodiments. In some embodiments, the semiconductor isolation feature 120 and the dielectric isolation features 122 are configured to block the leakage path of the bottom planar transistor formed from the lower fin elements 104L. In some embodiments, the dielectric isolation features 140 are made of silicon oxide (SiO₂), silicon nitride (SIN), silicon carbide (SiC), silicon oxynitride (SiON), silicon carbon nitride (SiCN), silicon oxycarbonitride (SiOCN), and/or oxygen-doped silicon carbonitride (Si(O)CN).

In some embodiments, the formation of the dielectric isolation features 122 includes deposition a dielectric material for the dielectric isolation features 122 over the semiconductor structure 100, and etching back the dielectric material. In some embodiments, the semiconductor isolation feature 120 are made of non-doped silicon, and the dielectric isolation features 122 are made silicon oxide. In some embodiments, forming the semiconductor isolation feature 120 may reduce the difficulty of the deposition and etching back processes for forming the dielectric isolation features 122.

The source/drain features 126 are then grown in the source/drain recesses 120 from the expose surfaces of the second semiconductor layers 108 using an epitaxial growth process, as shown in FIG. 1C, in accordance with some embodiments. The epitaxial growth process may be MBE, MOCVD, or VPE, another suitable technique, or a combination thereof. In some embodiments, the source/drain features 126 abut the inner spacer layers 124 and the second semiconductor layers 108. In some embodiments, the source/drain features 126 have the facet surfaces. In some other embodiments, the source/drain features 126 may have curved surfaces in some other embodiments.

In some embodiments, the source/drain features 126 are made of any suitable semiconductor material for n-type semiconductor devices or p-type semiconductor devices. In some embodiments, the source/drain features 126 are doped. The concentration of the dopant in the source/drain features 126 in a range from about 1×10¹⁹ cm⁻³ to about 6×10²¹ cm⁻³. An annealing process may be performed on the semiconductor structure 100 to activate the dopants in the source/drain features 126, in accordance with some embodiments.

In some embodiments wherein the active regions 104 are to be formed as an N-type nanostructure device (such as n-channel nanostructure transistor), the source/drain features 126 are made of semiconductor materials such as SiP, SiAs, SiCP, SiC, Si, GaAs, another suitable semiconductor material, or a combination thereof. In some embodiments, the source/drain features 126 are doped with the n-type dopant during the epitaxial growth process. For example, the n-type dopant may be phosphorous (P) or arsenic (As). For example, the source/drain features 126 may be the epitaxially grown Si doped with phosphorous to form silicon: phosphor (Si:P) source/drain features and/or arsenic to form silicon: arsenic (Si:As) source/drain features.

In some embodiments wherein the active regions 104 are to be formed as a P-type nanostructure device (such as p-channel nanostructure transistor), the source/drain features 126 are made of semiconductor materials such as SiGe, Si, GaAs, another suitable semiconductor material, or a combination thereof. In some embodiments, the source/drain features 126 are doped with the p-type dopant during the epitaxial growth process. For example, the p-type dopant may be boron (B) or BF₂. For example, the source/drain features 126 may be the epitaxially grown SiGe doped with boron (B) to form a silicon germanium:boron (SiGe:B) source/drain feature.

FIGS. 1D-1 and 1D-2 are cross-sectional views of the semiconductor after the formation of a contact etching stop layer (CESL) 128 and a first interlayer dielectric layer (ILD) 130, corresponding to line Y-Y and line X-X, in accordance with some embodiments.

Line X-X is in a plan parallel to the longitudinal axis of the active region 104 (i.e., X direction) and through the active region 104. Line Y-Y is in a plan parallel to the longitudinal axis of the gate structure (i.e., Y direction) and across the source/drain region of the active region 104.

A contact etching stop layer 128 is formed over the semiconductor structure 100 to cover the source/drain features 126, as shown in FIGS. 1D-1 and 1D-2, in accordance with some embodiments. The contact etching stop layer 128 is further formed along, and covers, the sidewalls of the gate spacer layers 118 and the top surface of the dielectric isolation structure 122, in accordance with some embodiments.

In some embodiments, the contact etching stop layer 128 is made of dielectric material, such as silicon nitride (SiN), silicon oxynitride (SiON), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, the contact etching stop layer 128 are made of low-k dielectric materials with the dielectric constant lower than 10. In some embodiments, a dielectric material for the contact etching stop layer 128 is globally and conformally deposited over the semiconductor structure 100 using CVD (such as LPCVD, PECVD, HDP-CVD, or HARP), ALD, another suitable method, or a combination thereof.

Afterward, a first interlayer dielectric layer 130 is formed over the contact etching stop layer 128, as shown in FIGS. 1D-1 and 1D-2, in accordance with some embodiments. The first interlayer dielectric layer 130 overfills the space between the dummy gate structures 112, in accordance with some embodiments. In some embodiments, the first interlayer dielectric layer 130 is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), and/or another suitable dielectric material. In some embodiments, the contact etching stop layer 128 is made of low-k dielectric materials with the dielectric constant lower than 10 such as lower than 4.2.

In some embodiments, the first interlayer dielectric layer 130 and the contact etching stop layer 128 are made of different materials and have a great difference in etching selectivity. For example, the contact etching stop layer 128 is a silicon nitride layer, and the first interlayer dielectric layer 130 is a silicon oxide layer. In some embodiments, the dielectric material for the first interlayer dielectric layer 130 is deposited using such as CVD (such as HDP-CVD, PECVD, HARP or FCVD), another suitable technique, or a combination thereof. The dielectric materials for the contact etching stop layer 128 and the first interlayer dielectric layer 130 above the top surface of the dummy gate electrode layer 116 are removed using such as CMP, in accordance with some embodiments.

FIGS. 1E-1 and 1E-2 are cross-sectional views of the semiconductor after the formation of gate trenches 134 and gaps 136, corresponding to line Y-Y and line X-X, in accordance with some embodiments.

The dummy gate structures 112 are removed using an etching process to form gate trenches 134 between the gate spacer layers 118, as shown in FIG. 1E-2, in accordance with some embodiments. In some embodiments, the gate trenches 134 expose the channel regions of the active regions 104. In some embodiments, the gate trenches 134 further expose the sidewalls of the gate spacer layers 118 facing the channel region. In some embodiments, the etching process includes one or more etching processes. For example, when the dummy gate electrode layer 116 is made of polysilicon, a wet etchant such as a tetramethylammonium hydroxide (TMAH) solution may be used to selectively remove the dummy gate electrode layer 116. For example, the dummy gate dielectric layer 114 may be thereafter removed using a plasma dry etching, a dry chemical etching, and/or a wet etching.

Afterward, an etching process is performed on the first semiconductor layers 106 of the active regions 104 to form gaps 136, as shown in FIG. 1E-2, in accordance with some embodiments. The inner spacer layers 124 may be used as an etching stop layer in the etching process, which may protect the source/drain features 126 from being damaged. In some embodiments, the etching process includes a selective wet etching process, such as APM (e.g., ammonia hydroxide-hydrogen peroxide-water mixture) etching process. In some embodiments, the wet etching process uses etchants such as ammonium hydroxide (NH₄OH), TMAH, ethylenediamine pyrocatechol (EDP), and/or potassium hydroxide (KOH) solutions.

The gaps 136 are formed between adjacent second semiconductor layers 108 and between the lowermost second semiconductor layers 108 and the lower fin elements 104L, in accordance with some embodiments. In some embodiments, the gaps 136 also expose the sidewalls of the inner spacer layers 124 facing the channel regions.

After the one or more etching processes, the four main surfaces of the second semiconductor layers 108 are exposed, in accordance with some embodiments. The exposed second semiconductor layers 108 form nanostructures, in accordance with some embodiments. The nanostructures 108 are stacked vertically and spaced apart from one other, in accordance with some embodiments. The nanostructures 108 function as channel layers of the resulting semiconductor devices (e.g., nanostructure transistors such as GAA transistors), in accordance with some embodiments. In some embodiments, a trimming process may be performed on the nanostructures 108 to shape the profiles of the nanostructures 108, e.g., rounding the corners of the nanostructures 108.

FIG. 1F is a perspective view of the semiconductor structure 100 after the formation final gate stacks 138, in accordance with some embodiments of the disclosure. FIGS. 1F-1 and 1F-2 are cross-sectional views cut along line Y-Y and line X-X of FIG. 1F, in accordance with some embodiments.

Final gate stacks 138 are formed in the gate trenches 134 and gaps 136, thereby wrapping around the nanostructures 108, as shown in FIGS. 1F and 1F-2, in accordance with some embodiments. In some embodiments, the final gate stacks 138 extend in the Y direction. The final gate stacks 138 have longitudinal axes parallel to the Y direction, in accordance with some embodiments. In some embodiments, each of the final gate stacks 138 includes an interfacial layer 140, a gate dielectric layer 142 and a metal gate electrode layer 144, as shown in FIGS. 1F and 1F-2, in accordance with some embodiments.

The interfacial layer 140 is formed on the exposed surfaces of the nanostructures 108 and the exposed top surfaces of the lower fin elements 104L, in accordance with some embodiments. The interfacial layer 140 wraps around the nanostructures 108, in accordance with some embodiments. In some embodiments, the interfacial layer 140 is made of a chemically formed silicon oxide. In some embodiments, the interfacial layer 140 is nitrogen-doped silicon oxide. In some embodiments, the interfacial layer 140 is formed using one or more cleaning processes such as including ozone (O₃), ammonia hydroxide-hydrogen peroxide-water mixture, and/or hydrochloric acid-hydrogen peroxide-water mixture. Semiconductor material from the nanostructures 108 and the lower fin elements 104L is oxidized to form the interfacial layer 140, in accordance with some embodiments.

The gate dielectric layer 142 is formed conformally along the interfacial layer 140 to wrap around the nanostructures 108, in accordance with some embodiments. The gate dielectric layer 142 is also conformally formed along the sidewalls of the gate spacer layers 118 facing the channel region, in accordance with some embodiments. The gate dielectric layer 142 is also conformally formed along the sidewalls of the inner spacer layers 124 facing the channel region, in accordance with some embodiments.

The gate dielectric layer 142 may be high-k dielectric layer. In some embodiments, the high-k dielectric layer is dielectric material with high dielectric constant (k value), for example, greater than 10, such as greater than 20, such as greater than 30. In some embodiments, the high-k dielectric layer includes hafnium oxide (HfO₂), TiO₂, HfZrO, Ta₂O₃, HfSiO₄, ZrO₂, ZrSiO₂, LaO, Al₂O₃, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr) TiO₃ (BST), a combination thereof, or another suitable material. The high-k dielectric layer may be deposited using ALD, PVD, CVD, and/or another suitable technique.

The metal gate electrode layer 144 is formed to overfill remainders of the gate trenches 134 and gaps 136, in accordance with some embodiments. In some embodiments, the metal gate electrode layer 144 is made of more than one conductive material, such as a metal, metal alloy, conductive metal oxide and/or metal nitride, another suitable conductive material, and/or a combination thereof. For example, the metal gate electrode layer 144 may be made of Ti, Ag, Al, TiAlN, TaC, TaCN, TaSiN, Mn, Zr, TiN, TaN, Ru, Mo, WN, Cu, W, Re, Ir, Co, Ni, another suitable conductive material, or multilayers thereof.

The metal gate electrode layer 144 may be a multi-layer structure with various combinations of a diffusion barrier layer, work function layers with a selected work function to enhance the device performance (e.g., threshold voltage) for n-channel FETs or p-channel FETs, a capping layer to prevent oxidation of work function layers, a glue layer to adhere work function layers to the next layer, and a metal filling layer to reduce the total resistance of the gate stacks, and/or another suitable layer. The metal gate electrode layer 144 may be formed using ALD, PVD, CVD, e-beam evaporation, or another suitable technique.

The topmost nanostructures 108 are denoted as 108_1, as shown in FIG. 1F-2. The portions of the metal gate electrode layers 144 formed above the topmost nanostructures 108_1 between the gate spacer layers 118 are referred to as top gate electrode layers TG, in accordance with some embodiments. The portions of the metal gate electrode layers 144 formed under the topmost nanostructures 108_1 between the inner spacer layers 124 are referred to as inner gate electrode layers IG, in accordance with some embodiments. The inner gate electrode layers IG are located between the nanostructures 108 and between the bottommost nanostructures 108 and the lower fin elements 104L, in accordance with some embodiments.

A planarization process such as CMP may be performed on the semiconductor structure 100 to remove the materials of the gate dielectric layer 142 and the metal gate electrode layer 144 formed above the top surface of the first interlayer dielectric layer 130, in accordance with some embodiments.

The final gate stacks 138 engage the channel regions so that current can flow between the source/drain features 126 during operation. The final gate stacks 138 that are wrapped around the nanostructures 108 combine with the neighboring source/drain features 126 to form nanostructure transistors, e.g., n-channel nanostructure transistors and/or p-channel nanostructure transistors.

FIG. 1G is a perspective view of the semiconductor structure 100 after an etching process, in accordance with some embodiments of the disclosure. FIGS. 1G-1 and 1G-2 are cross-sectional views cut along line Y-Y and line X-X of FIG. 1G, in accordance with some embodiments. FIG. 1G-3 is an enlarged view of FIG. 1G-2 to illustrate more details.

An etching process is performed on the semiconductor structure 100 to recess the gate spacer layers 118 and the vertical portions of the gate dielectric layer 142 along the sidewalls of the gate spacer layers 118, as shown in FIGS. 1G to 1G-3, in accordance with some embodiments. In the etching process, the first interlayer dielectric layer 130 and the vertical portions of the contact etching stop layer 128 along the gate spacer layers 118 are also recessed, in accordance with some embodiments. Trenches 145 are formed between the top gate electrode layers TG and the recessed first interlayer dielectric layer 130 (and the contact etching stop layer 128 and the source/drain features 126), in accordance with some embodiments.

In some embodiments, the etching process may be an anisotropic etching process such as dry plasma etching, an isotropic etching process such as dry chemical etching, remote plasma etching or wet chemical etching, and/or a combination thereof. In some embodiments, the etching process is performed without an additional patterned mask. In some embodiments, a mask layer (not shown) may be formed to cover the metal gate electrode layer 144.

The vertical portions of the contact etching stop layer 128 along the gate spacer layers 118 are completely removed in the etching process, thereby exposing a portion 126S of the surface of the source/drain features 126, as shown in FIG. 1G-3, in accordance with some embodiments. In some other embodiments, the vertical portions of the contact etching stop layer 128 along the gate spacer layers 118 may be partially removed, and the surface of the source/drain features 126 remain completely covered by the contact etching stop layer 128.

After the etching process, the top surface 142T of the recessed gate dielectric layer 142 is lower than the top surfaces 118T of the recessed gate spacer layers 118, in accordance with some embodiments. In some other embodiments, the top surface 142T of the recessed gate dielectric layer 142 may be substantially level with the top surfaces 118T of the recessed gate spacer layers 118.

The gate dielectric layers 142 over the topmost nanostructures 108_1 include vertical portions 142A formed along the sidewalls of the gate spacer layers 118 and horizontal portions 142B formed along the top surface of the topmost nanostructures 108_1, in accordance with some embodiments. Due to growing on the surfaces with different surface characteristics, the vertical portions 142A and the horizontal portions 142B of the gate dielectric layer 142 may have different crystalline characteristics. For example, in some embodiments, in the deposition process, the high-k dielectric material of the gate dielectric layer 142 is formed on the amorphous surface provided by the gate spacer layers 118 and crystalline surface provided by the interfacial layer 120 (and underlying nanostructure 108). As a result, the vertical portions 142A arc predominantly amorphous, and horizontal portions 142B are predominantly crystalline, and thus they have different etching selectivity in the etching process for recessing the gate dielectric layers 142.

As the etch proceeds vertically downward from the tops of the vertical portions 142A toward the horizontal portions 142B, the etch rate gradually slows down due to the increasing crystallinity of the high-k dielectric material of the gate dielectric layer 142, in accordance with some embodiments. That is, the etching rate for etching the lower part of the vertical portion 142A is slower than the etching rate for etching the upper part of the vertical portion 142A, in accordance with some embodiments. As a result, the horizontal portion 142B of the gate dielectric layer 142 may be used as an etching stop layer in the etching process, in accordance with some embodiments.

In some embodiments, the etching process stops at the bottom part of the vertical portions 142A, as shown in FIGS. 1G-2 and 1G-3. In some other embodiments, the etching may finally self-stop on the horizontal portions 142B with high crystallinity, in accordance with some embodiments. Therefore, the etching process for recessing the gate dielectric layer 142 may be bettered controlled because of the different etching selectivity between the vertical portions 142A and the horizontal portions 142B of the gate dielectric layer 142, in accordance with some embodiments. The horizontal portions 142B of the gate dielectric layer 142 remains covering the top surfaces of the topmost nanostructures 108_1, thereby preventing the channel regions from being oxidized, in accordance with some embodiments.

In some embodiments, the recessed gate dielectric layer 142 has a height H1 over the topmost nanostructure 108_1. In some embodiments, the height H1 is in a range from about 1 nm to about 10 nm.

The top surfaces 118T of the recessed gate spacer layers 118 are lower than the tops 126T of the source/drain features 126 and the top surfaces 128T of the contact etching stop layer 128, in accordance with some embodiments. The top surface 130T of the recessed first interlayer dielectric layer 130 is lower than the top surfaces 144T of the metal gate electrode layers 144, in accordance with some embodiments.

Since the thickness of the gate dielectric layer 142 is thin (e.g., about 1-2 nm), in the case of not recessing the gate spacer layer 118 and the contact etching stop layer 128, the process difficulty of etching the dielectric layer (e.g., substantially anisotropic, vertical etching) may be high. Therefore, by recessing the gate spacer layers 118 and the contact etching stop layer 128, the gate dielectric layer 142 may be etched vertically and laterally, thereby reducing the process difficulty of recessing the gate dielectric layer 142.

In the etching process, the upper portion of the sidewalls 144S of the top gate electrode layers TG are exposed from the recessed gate dielectric layer 142, in accordance with some embodiments. After the etching process, the top gate electrode layer TG includes upper portions 144A protruding from the gate dielectric layer 142 and lower portions 144B nested within the gate dielectric layer 142, as shown in FIG. 1G-3.

In some embodiments, the upper portions 144A of the top gate electrode layers TG exposed from the recessed gate dielectric layer 142 are laterally recessed by a distance D. In some embodiments, the distance D is in a range from about 1 to about 2 nm. The recessed top gate electrode layers TG may improve the risk of leakage between the top gate electrode layers and a subsequently formed contact plug may be high. This will be discussed in detail later. In some other embodiments, the upper portions of the sidewalls 144S of the top gate electrode layers TG are not laterally recessed.

In some embodiments, a connecting surface 144S1 connected between the sidewall of the upper portion 144A and the sidewall of the lower portion 144B may be curved (e.g., concave). In some embodiments, the connecting surface 144S1 may be linearly inclined.

In some embodiments, the upper portions 144A of the top gate electrode layers TG have a dimension D1 in the X direction, which is in a range from about 3 nm to about 15 nm. In some embodiments, the lower portions 144B of the top gate electrode layers TG have a dimension D2 in the X direction, which is in a range from about 5 nm to about 15 nm. In some embodiments, the dimension D1 is less than the dimension D2. In some other embodiments, the dimension D1 of the upper portions 144A is substantially equal to the dimension D2 of the lower portions 144B.

In some embodiments, the ratio (D1/D2) of the dimension D1 to the dimension D2 is in a range from about 0.6 to about 1. If the ratio (D1/D2) is too small, the risk that the top gate electrode layers TG collapses or wiggles may increase. In some embodiments, the final gate stack 138 has a critical dimension D3 in the X direction in a range from 10 nm to about 20 nm.

FIGS. 1H-1 and 1H-2 are cross-sectional views of the semiconductor after the formation of a lining layer 146 and a filling layer 148, corresponding to line Y-Y and line X-X, in accordance with some embodiments.

A lining layer 146 is formed over the semiconductor structure 100, as shown in FIGS. 1H-1 and 1H-2, in accordance with some embodiments. The lining layer 146 extends along, and covers, the top surfaces 144T and the upper portion of the sidewalls 144S of the top gate electrode layers TG, in accordance with some embodiments. The lining layer 146 further extends along, and covers, the top surfaces 118T of the gate spacer layers 118, and the top surface 142T of the gate dielectric layer 142, in accordance with some embodiments. The lining layer 146 further extends along, and covers, the exposed portion 126S of the surface of the source/drain features 126, the exposed side surfaces of the contact etching stop layer 128, and the top surface 130T and the sidewalls of the first interlayer dielectric layer 130, in accordance with some embodiments.

The upper portions 144A of the top gate electrode layers TG are surrounded by and in direct contact with the lining layer 146, while the lower portions 144B of the top gate electrode layers TG are surrounded by and in direct contact with the gate dielectric layer 142, in accordance with some embodiments.

In some embodiments, the lining layer 146 is made of dielectric material, such as silicon nitride (SiN), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, the lining layer 146 are made of low-k dielectric materials with the dielectric constant lower than 10. In some embodiments, a dielectric material for the lining layer 146 is globally and conformally deposited over the semiconductor structure 100 using CVD (such as LPCVD, PECVD, HDP-CVD, or HARP), ALD, another suitable method, or a combination thereof. In some embodiments, the thickness of the lining layer 146 is in a range from about 3 nm to about 10 nm. In some embodiments, the thickness of the lining layer 146 is greater than the thickness of the gate dielectric layer 142.

A filling layer 148 is formed over the lining layer 146, as shown in FIGS. 1H-1 and 1H-2, in accordance with some embodiments. The filling layer 148 overfills the space between the top gate electrode layers TG, in accordance with some embodiments. In some embodiments, the filling layer 148 is made of dielectric material such as silicon oxide (SiO₂), silicon oxynitride (SiON), silicon nitride (SiN), silicon carbide (SiC), oxygen-doped silicon carbide (SiC:O), oxygen-doped silicon carbonitride (Si(O)CN), or a combination thereof. In some embodiments, the filling layer 148 is made of low-k dielectric materials with the dielectric constant lower than 10. In some embodiments, the k-value of the filling layer 148 may be lower than a k-value of silicon oxide (SiO), such as lower than 4.2, equal to or lower than about 3.9, such as in a range from about 3.5 to about 3.9. In some embodiments, the filling layer 148 is deposited using such as CVD (such as HDP-CVD, PECVD, HARP or FCVD), another suitable technique, or a combination thereof.

In some embodiments, the filling layer 148 and the lining layer 146 are made of different materials and have a great difference in etching selectivity. In some embodiments, the dielectric constant of the filling layer 148 is lower than the dielectric constant of the lining layer 146. In an embodiment where the lining layer 146 is a silicon nitride layer and the filling layer 148 is a silicon oxide layer, the lining layer 146 may prevent the upper portions 144A of the top gate electrode layers TG from being oxidized, thereby reducing the risk of negatively affecting threshold voltage of the resulting semiconductor device.

FIG. 1I is a perspective view of the semiconductor structure 100 after a planarization process, in accordance with some embodiments of the disclosure. FIGS. 1I-1 and 1I-2 are cross-sectional views cut along line Y-Y and line X-X of FIG. 1I, in accordance with some embodiments. FIG. 1I-3 is an enlarged view of FIG. 1I-2 to illustrate more details.

A planarization process is performed on the semiconductor structure 100, thereby exposing the top gate electrode layers TG, as shown in FIGS. 1I to 11-3, in accordance with some embodiments. The planarization process may be CMP or an etching-back process, in accordance with some embodiments. The planarization process is performed to thin down the top gate electrode layers TG until the top gate electrode layers TG have desired heights, in accordance with some embodiments.

In some embodiments, the portion of the filling layer 148 over the first interlayer dielectric layer 130 and the portion of the lining layer 146 along the top surfaces 130T of the first interlayer dielectric layer 130 are also removed, thereby exposing the top surfaces 130T of the first interlayer dielectric layer 130, as shown in FIGS. 1I-3.

After the planarization process, the top surfaces 144T of the top gate electrode layers TG, the top surfaces 146T of the lining layer 146, the top surfaces 148T of the filling layer 148 and the top surfaces 130T of the first interlayer dielectric layer 130 are substantially coplanar, as shown in FIG. 1I-3, in accordance with some embodiments.

In some embodiments, the top gate electrode layers TG together with the gate dielectric layer 142 has a height H2 (in the Z direction) over the topmost nanostructure 108_1. In some embodiments, the height H2 is in a range from about 10 nm to about 30 nm. In some embodiments, the ratio (H1/H2) of the height H1 of the height H2 is in a range from about 0.05 to about 0.5. If the ratio (H1/H2) is too large (e.g., greater than 0.5), the risk of leakage between the top gate electrode layers and a subsequently formed contact plug may be high. This will be discussed in detail later.

FIG. 1J is a perspective view of the semiconductor structure 100 after the formation of an etching stop layer 150, a second interlayer dielectric layer 152 and contact plugs 154, in accordance with some embodiments of the disclosure. FIGS. 1J-1 and 1J-2 are cross-sectional views cut along line Y-Y and line X-X of FIG. 1J, in accordance with some embodiments.

An etching stop layer 150 is formed over the semiconductor structure 100, as shown in FIGS. 1J to 1J-2, in accordance with some embodiments. In some embodiments, the etching stop layer 150 is made of dielectric material, such as silicon nitride (SiN), silicon oxynitride (SiON), silicon oxide (SiO₂), silicon carbide (SIC), oxygen-doped silicon carbide (SiC:O), oxygen-doped silicon carbonitride (Si(O)CN), or a combination thereof. In some embodiments, a dielectric material for the etching stop layer 150 is deposited using CVD (such as LPCVD, PECVD, HDP-CVD, or HARP), ALD, another suitable method, or a combination thereof.

A second interlayer dielectric layer 152 is formed over the etching stop layer 150, as shown in FIGS. 1J to 1J-2, in accordance with some embodiments. In some embodiments, the second interlayer dielectric layer 152 is made of dielectric material, such as USG, BPSG, FSG, PSG, BSG, or another suitable dielectric material. In some embodiments, the second interlayer dielectric layer 152 and etching stop layer 150 are made of different materials and have a great difference in etching selectivity. In some embodiments, the etching stop layer 150 is made of silicon nitride, and the second interlayer dielectric layer 152 is made of silicon oxide. In some embodiments, the second interlayer dielectric layer 152 is deposited using such as CVD (such as HDP-CVD, PECVD, HARP or FCVD), another suitable technique, or a combination thereof.

Contact plugs 154 are formed through the second interlayer dielectric layer 152, the etching stop layer 150, the first interlayer dielectric layer 130 and the contact etching stop layer 128, as shown in FIGS. 1J-1 to 1J-2, in accordance with some embodiments. The contact plugs 154 land on and are electrically connected to the source/drain features 126, in accordance with some embodiments.

In some embodiments, the formation of the contact plugs 154 includes patterning the semiconductor structure 100 to form contact openings (where the contact plugs 154 are to be formed) using photolithography and etching processes until the source/drain features 126 are exposed. The etch process may include dry etching such as reactive ion etch (RIE), neutral beam etch (NBE), inductive coupled plasma (ICP) etch, capacitively coupled plasma (CCP) etch, another suitable method, or a combination thereof.

Contact liner 156 is formed along the sidewalls of the contact opening using a deposition process and an etching back process, in accordance with some embodiments. In some embodiments, the contact liner 156 is made of an insulating material such as a dielectric material (e.g., SiC, LaO, AlO, AlON, ZrO, HfO, SiN, ZnO, ZrN, ZrAlO, TiO, TaO, YO, TaCN, ZrSi, SiOCN, SiOC, SiCN, SiN, HfSi, or SiO); or undoped silicon (Si).

Silicide layers 158 are formed on the exposed surfaces of the source/drain features 126. In some embodiments, the silicide layers 158 are made of WSi, NiSi, TiSi and/or CoSi. In some embodiments, the formation of the silicide layers 158 includes depositing a metal material followed by one or more annealing processes. The semiconductive material (e.g., Si) from the source/drain features 126 reacts with the metal material to form the silicide layers 158, in accordance with some embodiments. Unreacted metal material is then removed, e.g., using wet etching.

Afterward, one or more conductive materials for the contact plugs 154 are deposited to overfill the contact openings, in accordance with some embodiments. In some embodiments, one or more conductive materials are deposited using CVD, PVD, e-beam evaporation, ALD, electroplating (ECP), electroless deposition (ELD), another suitable method, or a combination thereof to overfill the contact openings. The one or more conductive materials over the upper surface of the second interlayer dielectric layer 146 are planarized using, for example, CMP.

The contact plugs 154 may have a multilayer structure. For example, a barrier/adhesive layer (not shown) may optionally be deposited along the sidewalls and the bottom surfaces of the contact openings. The barrier/adhesive layer may be made of tantalum (Ta), tantalum nitride (TaN), titanium (Ti), titanium nitride (TiN), cobalt tungsten (CoW), another suitable material, or a combination thereof. A metal bulk layer is then deposited on the barrier/adhesive layer (if formed) to fill the remainder of the contact openings. In some embodiments, the metal bulk layer is made of one or more conductive materials with low resistance and good gap-fill ability, for example, cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), another suitable metal material, or a combination thereof.

As the scale of semiconductor devices continues to shrink, one of the design challenges of semiconductor devices is to scaling down the gate-to-gate pitch P, as shown in FIG. 1J-2. The scaling of the gate-to-gate pitch P can be achieved by shrinking the critical dimension D3 of the final gate stack 138, the critical dimension D4 of the contact plug 154, and/or the spacing between the final gate stack 138 and the contact plug 154.

However, the shrinkage of the critical dimension of the gate stack (or the dummy gate structure) may degrade the gap-filling capability of the metal gate electrode material(s), thereby negatively affecting the threshold voltage of the resulting semiconductor device. The shrinkage of the critical dimension of the contact plug may reduce the landing area of the contact plug on the source/drain feature, thereby increasing the resistance of the resulting semiconductor device.

Furthermore, the shrinkage of the spacing between the gate stack and the contact plug is limited by the capability of the photolithography process for forming the contact opening (e.g., overlay window). In the instances in which the contact plug is offset toward the final gate stack, the risk of leakage between the top gate electrode layer and the contact plug may significantly increase, because the gate dielectric layer 142 may contain conductive material (e.g., titanium) and/or crystalline defects and may have electrical conductivity to serve as a leakage path. The most prone location for leakage may be on top surface of the top gate electrode layer as this is the closest spacing between the gate stack and the contact plug.

In accordance with some embodiments of the present disclosure, the gate dielectric layer 142 is recessed after the formation of the final gate stack 138 so as to reduce the dimension of the top portion of the final gate stack 138 (i.e., substantially equal to dimension D1 of the upper portion 144A of the top gate electrode layer TG) without degrading the gap-filling capability of the metal gate electrode material(s), and the spacing S between the contact plug 154 and the final gate stack 138 may thus increase. That is, because the gate dielectric layer 142 that may serve as a leakage path is recessed, the window of electrical isolation between the contact plug 154 and the final gate stack 138 may increase.

When the contact plug 154 is offset toward the final gate stack 144, the risk of leakage between the top gate electrode layer TG and the contact plug 154 may not significantly increase. Therefore, the reliability (e.g., the window of time-dependent dielectric breakdown (TDDB)) of resulting semiconductor device may improve. In addition, the overlay window of the photolithography process for forming the contact opening 150 may be relaxed, which may facilitate the scaling down of the gate-to-gate pitch.

Furthermore, the upper portion 144A of the top gate electrode layer TG is surrounded by the lining layer 146 which has a lower dielectric constant than the gate dielectric layer 142 and a better electrical isolation than the gate dielectric layer 142, in accordance with some embodiments. Therefore, the parasitic capacitance between the top gate electrode layer TG and the contact plug 154 may reduce, thereby improving the performance (e.g., speed) of the resulting semiconductor device, in accordance with some embodiments.

It should be understood that the semiconductor structure 100 may undergo further CMOS processes to form various features over the semiconductor structure, such as a multilayer interconnect structure (e.g., conductive vias, metal lines, inter metal dielectric layers, passivation layers, etc.).

FIGS. 2A-1 through 2D-2 are schematic views illustrating the formation of a semiconductor structure 200 at various intermediate stages, in accordance with some embodiments of the disclosure. The embodiments of FIGS. 2A-1 through 2D-2 are similar to the embodiments of the FIGS. 1A through 1J-2, except that the first interlayer dielectric layer 130 and the contact etching stop layer 128 are severely recessed in the etching process for recessing the gate spacer layers 118 and the gate dielectric layer 142.

FIGS. 2A-1 and 2A-2 are cross-sectional views of the semiconductor structure 200 after an etching process, corresponding to line Y-Y and line X-X, in accordance with some embodiments.

Continuing from FIGS. 1G to 1G-3, an etching process is performed on the semiconductor structure 200 to recess the gate spacer layers 118 and the gate dielectric layer, as shown in FIGS. 2A-1 and 2A-2, in accordance with some embodiments. The vertical portions 142A of the gate dielectric layer 142 are substantially completely removed, and the etching process stops on the horizontal portion 142B of the gate dielectric layer 142 due to its with high crystallinity, in accordance with some embodiments. The gate spacer layers 118 over the topmost nanostructures 108_1 are removed so that the topmost nanostructures 108_1 are exposed from the trenches 145, in accordance with some embodiments.

The sidewalls 144S of the top gate electrode layers TG are entirely exposed from the gate dielectric layer 142, in accordance with some embodiments. The top surface 142T of the gate dielectric layer 142 is substantially level with the bottom surfaces of the top gate electrode layers TG, in accordance with some embodiments.

The second-topmost nanostructures 108 are denoted as 108_2, as shown in FIG. 2A-1. The topmost nanostructures 108_1 and the second-topmost nanostructures 108_2 are illustrated as dashed line in FIG. 2A-1, indicating that they are located behind or in front of the cross-section view. The contact etching stop layer 128 and the first interlayer dielectric layer 130 are also recessed, and etched to a position located a distance D5 below the top surface of the topmost nanostructure 108_1, thereby exposing the upper portion of the surfaces of the source/drain features 126, in accordance with some embodiments. In some embodiments, the distance D5 is less than about 30 nm.

In some embodiments, the top surfaces 128T of the contact etching stop layer 128 and the top surface 130T of the first interlayer dielectric layer 130 are substantially level with or higher than the top surfaces of the second-topmost nanostructures 108_2.

FIGS. 2B-1 and 2B-2 are cross-sectional views of the semiconductor structure 200 after the formation of a lining layer 146 and a filling layer 148, corresponding to line Y-Y and line X-X, in accordance with some embodiments.

A lining layer 146 is formed over the semiconductor structure 200, and a second interlayer dielectric layer 148 is formed over the lining layer 146, as shown in FIGS. 2B-1 and 2B-2, in accordance with some embodiments. The lining layer 146 extends along, and covers, the top surfaces 144T and the sidewalls 144S of the top gate electrode layers TG, in accordance with some embodiments. The lining layer 146 further extends along, and covers, the upper portion of the surfaces of the source/drain features 126, in accordance with some embodiments.

The lining layer 146 further covers the top surfaces of the topmost nanostructures 108_1 and top surface 142T of the gate dielectric layer 142, in accordance with some embodiments. The lining layer 146 further covers the top surfaces 128T of the contact etching stop layer 128 and the top surface 130T and sidewalls of the first interlayer dielectric layer 130, in accordance with some embodiments.

FIG. 2C is a perspective view of the semiconductor structure 200 after a planarization process, in accordance with some embodiments of the disclosure. FIGS. 2C-1 and 2C-2 are cross-sectional views cut along line Y-Y and line X-X of FIG. 2C, in accordance with some embodiments. FIG. 2C-3 is an enlarged view of FIG. 2C-2 to illustrate more details.

A planarization process is performed on the semiconductor structure 200, thereby exposing the top gate electrode layers TG, as shown in FIGS. 2C to 2C-3, in accordance with some embodiments. After the planarization process, the top surfaces 144T of the top gate electrode layers TG, the top surfaces 146T of the lining layer 146 and the top surfaces 148T of the filling layer 148 are substantially coplanar, as shown in FIG. 2C-3, in accordance with some embodiments.

In some embodiments, the height H1 of the gate dielectric layer 142 over the topmost nanostructure 108_1 is in a range from about 1 nm to about 2 nm. In some embodiments, the top gate electrode layers TG has a height H2 in a range from about 10 nm to about 30 nm. In some embodiments, the ratio (H1/H2) of the height H1 of the height H2 is in a range from about 0.05 to about 0.1. Because the vertical portions of the gate dielectric layer 142 over the topmost nanostructure 108_1 are completely removed, the risk of leakage between the top gate electrode layers and the contact plug may be further reduced.

FIGS. 2D-1 and 2D-2 are cross-sectional views of the semiconductor structure 200 after the formation of an etching stop layer 150, a second interlayer dielectric layer 152 and contact plugs 154, corresponding to line Y-Y and line X-X, in accordance with some embodiments.

An etching stop layer 150 is formed over the semiconductor structure 200, a second interlayer dielectric layer 152 is formed over the etching stop layer 150, and contact plugs 154 are formed through the second interlayer dielectric layer 152, the etching stop layer 150, the filling layer 148 and the lining layer 146, as shown in FIGS. 2D-1 and 2D-2, in accordance with some embodiments.

FIG. 3 illustrates a modification the semiconductor structure of FIG. 2C-3, in accordance with some embodiments of the disclosure. The embodiments of FIG. 3 are similar to the embodiments of the FIGS. 2A-1 through 2D-3, except that after the etching process for recessing the gate spacer layers 118 and the gate dielectric layer 142, the gate spacer layers 118 has a portion remaining on the top surfaces of the topmost nanostructure 108_1.

FIGS. 4A-1 through 4B-2 are cross-sectional views illustrating the formation of a semiconductor structure 300 at various intermediate stages, in accordance with some embodiments of the disclosure. The embodiments of FIGS. 4A-1 through 4B-2 are similar to the embodiments of the FIGS. 1A through 1J-2, except that the filling layer 148 and the lining layer 146 remain over the first interlayer dielectric layer 130 after a planarization process.

FIGS. 4A-1 and 4A-2 illustrate the semiconductor structure 300 after the formation of a planarization process, corresponding to line Y-Y and line X-X, in accordance with some embodiments.

Continuing from FIGS. 1I to 11-2, a planarization process is performed on the semiconductor structure 300, thereby exposing the top gate electrode layers TG, as shown in FIGS. 4A-1 and 4A-2, in accordance with some embodiments. In some embodiments, after the planarization process, the filling layer 148 and the lining layer 146 remain over the top surfaces 130T of the first interlayer dielectric layer 130. The top surfaces 144T of the top gate electrode layers TG, the top surfaces 146T of the lining layer 146 and the top surfaces 148T of the filling layer 148 are substantially coplanar, as shown in FIG. 4A-2, in accordance with some embodiments.

FIGS. 4B-1 and 4B-2 the semiconductor structure 300 after the formation of an etching stop layer 150, a second interlayer dielectric layer 152 and contact plugs 154, corresponding to line Y-Y and line X-X, in accordance with some embodiments.

An etching stop layer 150 is formed over the semiconductor structure 300, a second interlayer dielectric layer 152 is formed over the etching stop layer 150, and contact plugs 154 are formed through the second interlayer dielectric layer 152, the etching stop layer 150, the filling layer 148, the lining layer 146, the first interlayer dielectric layer 130 and the contact etching stop layer 128, as shown in FIGS. 4B-1 and 4B-2, in accordance with some embodiments.

FIGS. 5A-1 through 5D-2 are cross-sectional views illustrating the formation of a semiconductor structure 400 at various intermediate stages, in accordance with some embodiments of the disclosure. The embodiments of FIGS. 5A-1 through 5D-2 are similar to the embodiments of the FIGS. 1A through 1J-2, except that the top surface 128T of the etching stop layer 128 is exposed in the etching process for recessing the gate spacer layers 118 and the gate dielectric layer 142.

FIGS. 5A-1 and 5A-2 illustrate the semiconductor structure 400 after an etching process, corresponding to line Y-Y and line X-X, in accordance with some embodiments.

Continuing from FIGS. 1G to 1G-3, an etching process is performed on the semiconductor structure 400 to recess the gate spacer layers 118 and the gate dielectric layer, as shown in FIGS. 5A-1 and 5A-2, in accordance with some embodiments. In the etching process, the portion of the first interlayer dielectric layer 130 over the contact etching stop layer 128 are removed, thereby exposing the top surface 128T of the contact etching stop layer 128, in accordance with some embodiments.

FIGS. 5B-1 and 5B-2 illustrate the semiconductor structure 400 after the formation of a lining layer 146 and a filling layer 148, corresponding to line Y-Y and line X-X, in accordance with some embodiments.

A lining layer 146 is formed over the semiconductor structure 400, and a second interlayer dielectric layer 148 is formed over the lining layer 146, as shown in FIGS. 5B-1 and 5B-2, in accordance with some embodiments. The lining layer 146 extends along, and covers, the top surfaces 144T and the sidewalls 144S of the top gate electrode layers TG and the top surface 128T of the contact etching stop layer 128, in accordance with some embodiments.

FIGS. 5C-1 and 5C-2 illustrate the semiconductor structure 400 after a planarization process, corresponding to line Y-Y and line X-X, in accordance with some embodiments.

A planarization process is performed on the semiconductor structure 400, thereby exposing the top gate electrode layers TG, as shown in FIGS. 5C-1 and 5C-2, in accordance with some embodiments. In some embodiments, after the planarization process, the top surfaces 144T of the top gate electrode layers TG, the top surfaces 146T of the lining layer 146 and the top surfaces 148T of the filling layer 148 are substantially coplanar, as shown in FIG. 5C-2, in accordance with some embodiments.

FIGS. 5D-1 and 5D-2 illustrate the semiconductor structure 400 after the formation of an etching stop layer 150, a second interlayer dielectric layer 152 and contact plugs 154, corresponding to line Y-Y and line X-X, in accordance with some embodiments.

An etching stop layer 150 is formed over the semiconductor structure 400, a second interlayer dielectric layer 152 is formed over the etching stop layer 150, and contact plugs 154 are formed through the second interlayer dielectric layer 152, the etching stop layer 150, the filling layer 148, the lining layer 146 and the contact etching stop layer 128, as shown in FIGS. 5D-1 and 5D-2, in accordance with some embodiments.

As described above, the method for forming the semiconductor structure includes recessing the gate dielectric layer 142 to expose the top gate electrode layer TG. As a result, the dimension of the top portion of the final gate stack 138 may be reduced, and the spacing S between the contact plug 154 and the final gate stack 138 may thus increase. Therefore, the reliability of resulting semiconductor device may improve. In addition, the overlay window of the photolithography process for forming the contact opening 150 may be relaxed, which may facilitate the scaling down of the gate-to-gate pitch.

Furthermore, the top gate electrode layer TG is at least partially surrounded by the lining layer 146 which has a lower dielectric constant than the gate dielectric layer 142 and a better electrical isolation than the gate dielectric layer 142. Therefore, the parasitic capacitance between the top gate electrode layer TG and the contact plug 154 may be reduced, thereby improving the performance of the resulting semiconductor device, in accordance with some embodiments.

Resistance-capacitance (RC) delay has arisen as a significant challenge as reduced geometry sizes are implemented to achieve ICs with faster operating speeds (e.g., by reducing distances traveled by electrical signals), thereby negating some of the advantages achieved by scaling down and limiting further scaling down of ICs. RC delay generally indicates delay in electrical signal speed through an IC resulting from a product of resistance (R) (i.e., a material's opposition to flow of electrical current) and capacitance (C) (i.e., a material's ability to store electrical charge). Reducing both resistance and capacitance is thus desired to reduce RC delay and optimize performance of scaled down ICs. As IC technologies expand into sub-20 nm technology nodes, shrinking critical dimensions (e.g., gate lengths, gate pitches, fin pitches, dimensions of vias, dimensions of metal lines, via pitches, metal line pitches, etc.) have led to increases in parasitic capacitance, and thus increases in RC delay, that can no longer be ignored when designing scaled down ICs. For transistors, parasitic capacitance may arise from gate-to-source/drain capacitance and gate-to-source/drain contact capacitance. Materials separating a gate stack of a transistor from its source/drain features (e.g., gate spacers and/or high-k gate dielectric) and source/drain contacts (e.g., gate spacers, high-k gate dielectric, an interlevel dielectric (ILD) layer, etc.) can increase or decrease gate-to-source/drain capacitance and gate-to-source/drain contact capacitance, and thus increase or decrease a total parasitic capacitance of the transistor. Efforts for reducing total parasitic capacitance of the transistor are thus often directed to lowering a dielectric constant of the materials separating the gate stack from the source/drain features and/or the source/drain contacts.

The present disclosure recognizes that a high-k gate dielectric of the gate stack, which is typically implemented to improve transistor performance, also contributes to the total parasitic capacitance of the transistor. The high-k gate dielectric's contributions to parasitic capacitance, such as that between a gate electrode and a source/drain contact, have become increasingly prevalent and detrimental in transistors at scaled technology nodes. Further, electrically conductive sidewall portions of the high-k gate dielectric, such as those formed along sidewalls of the gate electrode, may undesirably result in an electrically conductive path between the gate electrode and the source/drain contact, which may degrade transistor performance. Further, time-dependent dielectric breakdown (TBBD) considerations may constrain a distance/spacing between the gate stack and the source/drain contact, which may further be limited by an overlay window corresponding with a lithography process used to form a source/drain contact opening in which the source/drain contact is formed. Such constraints on reducing distance/spacing between the gate stack and the source/drain contact limit further IC scaling.

The present disclosure provides for removing and/or recessing sidewall portions of a high-k gate dielectric to address such issues and/or improve contact gate isolation (e.g., isolation between a gate electrode and a source/drain contact), thereby improving transistor performance. In some embodiments, a gate structure includes a gate stack and gate spacers disposed along sidewalls of the gate stack, and the gate stack include a gate electrode disposed over a high-k gate dielectric. The high-k gate dielectric may wrap the gate electrode. For example, the high-k gate dielectric has sidewall portions between sidewalls of the gate electrode and the gate spacers and a bottom portion between the gate electrode and a semiconductor layer (e.g., a channel).

A contact gate isolation process may include recessing (e.g., by etching) the sidewall portions of the high-k gate dielectric and the gate spacers to form a contact gate isolation (CGI) opening that exposes the sidewalls of the gate electrode, forming a gate isolation liner along the sidewalls of the gate electrode that partially fills the CGI opening, and forming a gate isolation layer over the gate isolation liner that fills a remainder of the CGI opening. The gate isolation liner and the gate isolation layer may form a CGI structure over the gate spacers and/or the high-k gate dielectric, and the gate isolation liner may be disposed between the gate spacers and the sidewalls of the gate electrode. The gate isolation liner and the gate isolation layer each include a dielectric material having a dielectric constant that is less than a dielectric constant of the high-k gate dielectric, such as a dielectric material having a dielectric constant that is less than about 8. In some embodiments, the gate isolation liner and the gate isolation layer each include a dielectric material that includes silicon and oxygen, nitrogen, carbon, or a combination thereof. In some embodiments, a dielectric constant of the gate isolation layer is less than a dielectric constant of the gate isolation liner. In some embodiments, the gate isolation liner includes nitrogen, which may prevent and/or reduce oxidation of the gate electrode.

In some embodiments, the sidewall portions of the high-k gate dielectric have an amorphous structure and the bottom portion of the high-k gate dielectric has a crystalline structure. In such embodiments, an etching process for recessing the high-k gate dielectric may have different etching selectivity with respect to the sidewall portions of the high-k gate dielectric and the bottom portion of the high-k gate dielectric, such that the etching process may stop upon reaching the bottom portion of the high-k gate dielectric. The sidewall portions of the high-k gate dielectric may thus be easily removed relative to the bottom portion of the high-k gate dielectric, which can prevent and/or minimize damage to the underlying semiconductor layer (i.e., the underlying channel). In some embodiments, the recessing/etching partially removes the sidewall portions of the high-k gate dielectric, the sidewall portions of the high-k gate dielectric cover lower portions of the sidewalls of the gate electrode, and the gate isolation liner covers upper portions of the sidewalls of the gate electrode. In some embodiments, the recessing/etching completely removes the sidewall portions of the high-k gate dielectric, and the gate isolation liner covers the sidewalls of the gate electrode. In some embodiments, the recessing/etching reduces a width of the gate electrode (e.g., the gate electrode may be laterally etched, such that the gate electrode has a top width that is less than a bottom width).

In some embodiments, the recessing/etching reduces a thickness of an ILD layer and/or a contact etch stop layer (CESL). In such embodiments, the gate isolation liner and/or the gate isolation layer may be formed over a top surface of the ILD layer and/or a top surface of the CESL. In some embodiments, an ILD layer is removed after the recessing/etching of the high-k gate dielectric and/or gate spacers and before forming the gate isolation liner and/or gate isolation layer. In such embodiments, the gate isolation liner and/or the gate isolation layer may be formed over a CESL, a portion of which may be formed over an epitaxial source/drain. In some embodiments, the recessing/etching may remove a portion of an ILD layer and/or a CESL over a top surface of an epitaxial source/drain. In such embodiments, the gate isolation liner and/or the gate isolation layer may be formed over the epitaxial source/drain.

Embodiments of a semiconductor structure and the method for forming the same may be provided. The method for forming the semiconductor structure includes recessing the gate dielectric layer to expose the gate electrode layer, forming a lining layer to cover the exposed sidewalls of the gate stack. As a result, the dimension of the top portion of the gate stack may be reduced. Therefore, the overlay window of the photolithography process for forming the contact opening may be relaxed, which may facilitate the scaling down of the gate-to-gate pitch.

In some embodiments, a method for forming a semiconductor structure is provided. The method includes forming a channel layer over a substrate, forming gate spacer layers over the channel layer, forming a gate dielectric layer along sidewalls of the gate spacer layers and a top surface of the channel layer, forming a gate electrode layer over the gate dielectric layer to fill a trench between the gate spacer layers, recessing the gate dielectric layer to expose sidewalls of the gate electrode layer, and forming a lining layer to cover the sidewalls of the gate electrode layer exposed from the gate dielectric layer. In some embodiments, a dielectric constant of the lining layer is lower than a dielectric constant of the gate dielectric layer. In some embodiments, the method further includes laterally recessing the gate electrode layer while recessing the gate dielectric layer. In some embodiments, the channel layer comprises a plurality of nanostructures stacked vertically and spaced apart from each other.

In some embodiments, the method further includes forming a filling layer over the lining layer. The filling layer is made of a different material than the lining layer. In some embodiments, the method further includes planarizing the filling layer and lining layer until a top surface of the gate electrode layer is exposed. In some embodiments, the method further includes recessing the gate spacer layers while recessing the gate dielectric layer. After the gate spacer layers and the gate dielectric layer are recessed, a top surface of the gate dielectric layer is lower than top surfaces of the gate spacer layers.

In some embodiments, the method further includes forming a source/drain feature adjacent to the channel layer, forming a contact etching stop layer over the source/drain feature, forming an interlayer dielectric layer over the contact etching stop layer, and recessing the interlayer dielectric layer and the contact etching stop layer while recessing the gate dielectric layer. In some embodiments, after the interlayer dielectric layer and the contact etching stop layer are recessed, a top surface of the contact etching stop layer is lower than a top of the source/drain feature.

In some embodiments, the gate dielectric layer includes vertical portions along the sidewalls of the gate spacer layers and recessing the gate dielectric layer includes etching an upper portion of the vertical portions of the gate dielectric layer at a first etching rate and etching a lower portion of the vertical portions of the gate dielectric layer at a second etching rate that is slower than the first etching rate.

In some embodiments, a method for forming a semiconductor structure is provided. The method includes forming a dummy gate structure over an active region, forming a source/drain feature adjoining the active region, forming an interlayer dielectric layer over the source/drain feature, and replacing the dummy gate structure with a gate stack. The gate stack includes a gate dielectric layer over a gate electrode layer. The method further includes etching the interlayer dielectric layer and the gate dielectric layer to expose an upper portion of the gate electrode layer and forming a filling layer along the upper portion of the gate electrode layer. In some embodiments, the method further includes forming a contact plug through the filling layer and on the source/drain feature. In some embodiments, the contact plug further penetrates through the interlayer dielectric layer. In some embodiments, the method further includes forming a contact etching stop layer to cover the source/drain feature. The interlayer dielectric layer is formed over the contact etching stop layer and etching the interlayer dielectric layer and the gate dielectric layer may include removing the interlayer dielectric layer to expose a top surface of the contact etching stop layer. The contact plug may further penetrate through the contact etching stop layer.

In some embodiments, a semiconductor structure is provided. The semiconductor structure includes a plurality of nanostructures over a substrate, a source/drain feature adjoining the plurality of nanostructures, a gate dielectric layer over a topmost nanostructure in the nanostructures, a gate electrode layer over the gate dielectric layer, and a lining layer over the gate dielectric layer. The lining layer includes a first portion along and in direct contact with a sidewall of the gate electrode layer. In some embodiments, a dielectric constant of the lining layer is lower than a dielectric constant of the gate dielectric layer. In some embodiments, the semiconductor structure further includes a contact etching stop layer covering the source/drain feature and an interlayer dielectric layer over the contact etching stop layer. The lining layer includes a second portion along and in direct contact with a sidewall of the interlayer dielectric layer. In some embodiments, a portion of a surface of the source/drain feature is covered by and in direct contact with the lining layer. In some embodiments, a top surface of the topmost nanostructure is partially covered by and in direct contact with the lining layer. In some embodiments, the semiconductor structure further includes a filling layer over the lining layer. A top surface of the filling layer may be substantially level with a top surface of the interlayer dielectric layer. In some embodiments, the gate electrode layer includes an upper portion surrounded by the lining layer and a lower portion surrounded by the gate dielectric layer. The upper portion of the gate electrode layer may be narrower than the lower portion of the gate electrode layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a gate stack over a semiconductor layer, wherein the gate stack includes a gate electrode disposed over a gate dielectric, wherein the gate stack is disposed between a first epitaxial source/drain and a second epitaxial source/drain;
etching the gate dielectric to expose sidewalls of the gate electrode;
forming a gate isolation liner along the exposed sidewalls of the gate electrode; and
forming a source/drain contact to the first epitaxial source/drain.

2. The method of claim 1, further comprising:
forming gate spacers along sidewalls of the gate stack, wherein the gate dielectric is between the gate spacers and the sidewalls of the gate electrode; and
etching the gate spacers while etching the gate dielectric.

3. The method of claim 2, wherein the etching of the gate dielectric and the etching of the gate spacers forms a gap, the gate isolation liner partially fills the gap, and the method further comprises forming a gate isolation layer to fill a remainder of the gap.

4. The method of claim 2, wherein the etching of the gate spacers exposes the first epitaxial source/drain, the second epitaxial source/drain, or both, wherein the gate isolation liner is formed on the first epitaxial source/drain, the second epitaxial source/drain, or both.

5. The method of claim 2, further comprising forming a first dielectric layer before etching the gate dielectric and before etching the gate spacers, wherein the first dielectric layer includes an interlayer dielectric (ILD) layer disposed over a contact etch stop layer (CESL).

6. The method of claim 5, wherein the etching of the gate dielectric and the etching of the gate spacers forms a gap between the sidewalls of the gate electrode and the first dielectric layer, and the gate isolation liner partially fills the gap, and the method further comprises forming a second dielectric layer to fill a remainder of the gap.

7. The method of claim 5, further comprising etching the first dielectric layer while etching the gate spacers.

8. The method of claim 7, wherein the etching of the gate spacers and etching of the first dielectric layer exposes the first epitaxial source/drain, the second epitaxial source/drain, or both, wherein the gate isolation liner is formed on the first epitaxial source/drain, the second epitaxial source/drain, or both.

9. The method of claim 1, wherein the etching the gate dielectric reduces a width of the gate electrode.

10. A method comprising:
forming a channel layer over a substrate;
forming a gate structure over the channel layer by:
forming gate spacers,
forming a gate dielectric layer over the channel layer, wherein the gate dielectric layer is disposed along sidewalls of gate spacers, and
forming a gate electrode layer over the gate dielectric layer;
recessing the gate dielectric layer to expose sidewalls of the gate electrode layer; and
forming a lining layer to cover the exposed sidewalls of the gate electrode layer.

11. The method of claim 10, further comprising:
forming a filling layer over the lining layer, wherein a composition of the filling layer is different than a composition of the lining layer; and
performing a planarization process on the filling layer and lining layer, wherein the planarization process exposes the gate electrode layer.

12. The method of claim 10, further comprising recessing the gate spacers while recessing the gate dielectric layer, wherein after the recessing of the gate spacers and the recessing of the gate dielectric layer, a top surface of the gate dielectric layer is lower than top surfaces of the gate spacers.

13. The method of claim 10, further comprising:
forming a source/drain feature adjacent to the channel layer;
forming a contact etch stop layer over the source/drain feature;
forming an interlayer dielectric layer over the contact etch stop layer; and
recessing the interlayer dielectric layer and the contact etch stop layer while recessing the gate dielectric layer.

14. The method of claim 10, further comprising laterally recessing the gate electrode layer while recessing the gate dielectric layer.

15. A transistor comprising:
a semiconductor layer disposed between a first epitaxial source/drain and a second epitaxial source/drain;
a gate structure disposed over the semiconductor layer, wherein the gate structure includes a gate stack and gate spacers disposed along sidewalls of the gate stack, wherein:
the gate stack includes a gate electrode disposed over a high-k gate dielectric, wherein the high-k gate dielectric is disposed along lower portions of sidewalls of the gate electrode and the high-k gate dielectric is disposed between
the gate spacers and the lower portions of the sidewalls of the gate electrode; and
a gate isolation liner disposed along upper portions of sidewalls of the gate electrode, wherein the gate isolation liner is disposed over the gate spacers and the high-k gate dielectric.

16. The transistor of claim 15, wherein a width of a lower portion of the gate electrode is greater than a width of an upper portion of the gate electrode.

17. The transistor of claim 15, wherein the gate isolation liner extends below a top surface of the gate spacers, wherein a portion of the gate isolation liner is between the gate spacers and the lower portions of the sidewalls of the gate electrode.

18. The transistor of claim 15, further comprising an interlayer dielectric layer disposed over the first epitaxial source/drain and the second epitaxial source/drain, wherein the gate isolation liner physically contacts the interlayer dielectric layer.

19. The transistor of claim 15, further comprising a gate isolation layer disposed over and wrapped by the gate isolation liner.

20. The transistor of claim 19, wherein a dielectric constant of the gate isolation layer is less than a dielectric constant of the gate isolation liner.
